(19) United States
(12) Patent Application Publication
(10) Pub. No.: US 2025/0014930 A1
(43) Pub. Date: Jan. 9, 2025

(54) SUBSTRATE PROCESSING APPARATUS, METHOD OF PROCESSING SUBSTRATE, METHOD OF MANUFACTURING SEMICONDUCTOR DEVICE, AND RECORDING MEDIUM

(71) Applicant: KOKUSAI ELECTRIC CORPORATION, Tokyo (JP)

(72) Inventors: Tsukasa KAMAKURA, Toyama-shi (JP); Tetsuaki INADA, Toyama-shi (JP)

(73) Assignee: KOKUSAI ELECTRIC CORPORATION, Tokyo (JP)

(21) Appl. No.: 18/894,486

(22) Filed: Sep. 24, 2024

Related U.S. Application Data
(63) Continuation-in-part of application No. PCT/JP2022/034843, filed on Sep. 16, 2022.

(30) Foreign Application Priority Data
Mar. 25, 2022 (JP) 2022-049740

(51) Int. Cl. H01L 21/677; H01L 21/02; H01L 21/67; H01L 21/687

(52) U.S. Cl. CPC H01L 21/67763; H01L 21/67173; H01L 21/68707; H01L 21/0217

(57) ABSTRACT

Provided is a technique including: a first container mover capable of moving a container; a second container mover disposed at a position different from the first container mover and capable of moving the container; a plurality of process modules capable of processing a substrate in the container; a substrate carrier disposed between the first container mover and the second container mover, configured to be communicable with the plurality of process modules, and capable of carrying the substrate; a substrate carry robot provided in the substrate carrier and capable of carrying the substrate to the process module; a third container mover disposed between the first container mover and the second container mover, and capable of moving the container from the first container mover to the second container mover; and a controller.

### CROSS-REFERENCE TO RELATED APPLICATIONS

This application is a Bypass Continuation Application of PCT International Application No. PCT/JP2022/034843, filed on Sep. 16, 2022, in the WIPO, the international application being based upon and claiming the benefit of priority from Japanese Patent Application No. 2022-049740, filed on Mar. 25, 2022, in the Japanese Patent Office, the entire contents of which are incorporated herein by reference.

### BACKGROUND OF THE INVENTION

### Field

The present disclosure relates to a substrate processing apparatus, a method of processing a substrate, a method of manufacturing a semiconductor device, and a recording medium.

### Description of the Related Art

A substrate processing apparatus including a plurality of process chambers for processing substrate is known.

The substrate is transferred to and from a plurality of boats by one transfer machine.

### SUMMARY OF THE INVENTION

The present disclosure provides a technique capable of achieving cost reduction and throughput improvement by carrying a container in which a substrate is accommodated.

According to one aspect of the present disclosure, there is provided a technique including:
a first container mover capable of moving a container;
a second container mover disposed at a position different from the first container mover and capable of moving the container;
a plurality of process modules capable of processing a substrate in the container;
a substrate carrier disposed between the first container mover and the second container mover, configured to be communicable with the plurality of process modules, and capable of carrying the substrate;
a substrate carry robot provided in the substrate carrier and capable of carrying the substrate to the process module;
a third container mover disposed between the first container mover and the second container mover, and capable of moving the container from the first container mover to the second container mover; and
a controller.

### BRIEF DESCRIPTION OF THE DRAWINGS

FIG. 1 is an explanatory diagram (transverse cross-sectional view) illustrating a schematic configuration example of a substrate processing apparatus according to a first embodiment of the present disclosure.

FIG. 2 is a cross-sectional view taken along line α-α in the substrate processing apparatus illustrated in FIG. 1.

FIG. 3 is a cross-sectional view taken along line β-β in the substrate processing apparatus illustrated in FIG. 1.

FIG. 4 is an explanatory diagram (longitudinal sectional view) illustrating a schematic configuration example of a reactor illustrated in FIG. 1.

FIG. 5A is an explanatory diagram illustrating a schematic configuration example of a first gas supplier included in the reactor illustrated in FIG. 4.

FIG. 5B is an explanatory diagram illustrating a schematic configuration example of a second gas supplier included in the reactor illustrated in FIG. 4.

FIG. 5C is an explanatory diagram illustrating a schematic configuration example of an inert gas supplier included in the reactor illustrated in FIG. 4.

FIG. 5D is an explanatory diagram illustrating a schematic configuration example of an inert gas supplier included in the reactor illustrated in FIG. 4.

FIG. 6 is an explanatory diagram for describing a controller of the substrate processing apparatus according to the first embodiment of the present disclosure.

FIG. 7 is an explanatory diagram (transverse cross-sectional view) illustrating a schematic configuration example of a substrate processing apparatus according to a second embodiment of the present disclosure.

FIG. 8 is a cross-sectional view taken along line α-α in the substrate processing apparatus illustrated in FIG. 7.

FIG. 9 is a cross-sectional view taken along line β-β in the substrate processing apparatus illustrated in FIG. 7.

FIG. 10 is a cross-sectional view of a modified example of the substrate processing apparatus illustrated in FIG. 7 (corresponding to the cross-sectional view in FIG. 9).

FIG. 11 is an explanatory diagram (longitudinal sectional view) illustrating a schematic configuration example of a reactor illustrated in FIG. 7.

FIG. 12 is an explanatory diagram (transverse cross-sectional view) illustrating a schematic configuration example of a substrate processing apparatus according to a third embodiment of the present disclosure.

FIG. 13 is an explanatory diagram (transverse cross-sectional view) illustrating a schematic configuration example of a substrate processing apparatus according to a fourth embodiment of the present disclosure.

FIG. 14 is a cross-sectional view taken along line β-β in the substrate processing apparatus illustrated in FIG. 13.

FIG. 15 is an explanatory diagram (longitudinal cross-sectional view) illustrating a schematic configuration example of a substrate processing apparatus according to a fifth embodiment of the present disclosure.

### DETAILED DESCRIPTION

A description will hereinafter be given of some embodiments of the present disclosure with consultation of the drawings.

Note that the drawings used in the following description are all schematic and thus, for example, the dimensional relationship between each constituent element and the ratio between each constituent element in the drawings do not necessarily coincide with realities. In addition, the dimensional relationship between each constituent element, the ratio between each constituent element, and the like do not necessarily coincide among a plurality of drawings.

### First Embodiment

### (1) Configuration of Substrate Processing Apparatus

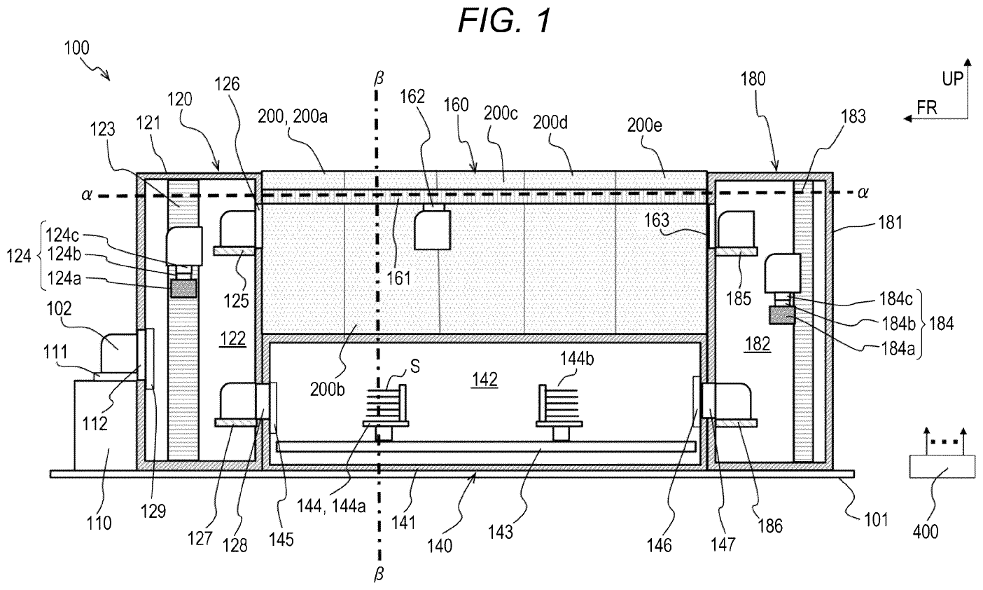

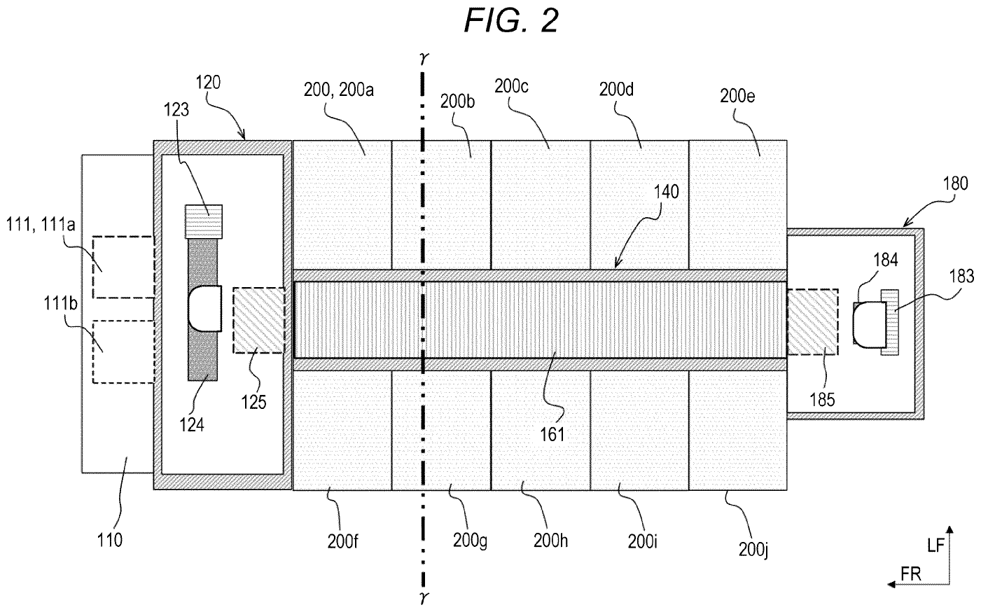

A schematic configuration of a substrate processing apparatus according to a first embodiment of the present disclosure will be described with reference to FIGS. 1 and 2. FIG. 1 is a transverse cross-sectional view illustrating a configuration example of a substrate processing apparatus according to the first embodiment of the present disclosure. FIG. 2 illustrates a configuration example of the substrate processing apparatus according to the first embodiment of the present disclosure, and is a longitudinal cross-sectional view taken along line α-α in FIG. 1.

In FIGS. 1 and 2, a substrate processing apparatus 100 according to the present embodiment processes a substrate S serving as a substrate. The substrate processing apparatus 100 mainly includes a load port 110, a first container mover 120, a second container mover 180, a substrate carrier 140, a third container mover 160, and a reactor 200 as an example of a process module.

Hereinafter, for convenience of description, in FIG. 1, a direction indicated by an arrow FR of the substrate processing apparatus 100 is referred to as front (front side) of the substrate processing apparatus 100, a direction opposite to the arrow FR is referred to as rear (rear side) of the substrate processing apparatus 100, a direction indicated by an arrow UP is referred to as up (upper side) of the substrate processing apparatus 100, and a direction opposite to the arrow UP is referred to as down (lower side). Further, in FIG. 2, a direction indicated by an arrow LF of the substrate processing apparatus 100 is referred to as left (left side) of the substrate processing apparatus 100, and a direction opposite to the arrow LF is referred to as right (right side). Further, the front (front side), the rear (rear side), the up (upper side), the down (lower side), the left (left side), and the right (right side) of the substrate processing apparatus 100 may be simply referred to as the front (front side), the rear (rear side), the up (upper side), the down (lower side), the left (left side), and the right (right side). Note that a right-left direction of the substrate processing apparatus 100 may be referred to as a width direction or a lateral direction, a front-rear direction of the substrate processing apparatus 100 may be referred to as a depth direction, or an up-down direction of the substrate processing apparatus 100 may be referred to as a height direction.

As illustrated in FIGS. 1 and 2, in the substrate processing apparatus 100, the load port 110 and the first container mover 120 are arranged on the front side, and the second container mover 180 is arranged on the rear side. The substrate carrier 140, the third container mover 160, and a plurality of the reactors 200 are disposed between the first container mover 120 and the second container mover 180. Specifically, the substrate carrier 140 is disposed on a lower side in the substrate processing apparatus 100 on a center side in the width direction of the substrate processing apparatus 100. On the other hand, the third container mover 160 is disposed on an upper side in the substrate processing apparatus 100 on the center side in the width direction of the substrate processing apparatus 100. Note that, in the present embodiment, the third container mover 160 is disposed above the substrate carrier 140. Further, the plurality of reactors 200 is arranged on both sides of the substrate carrier 140 in the width direction. In the present embodiment, as an example, five reactors 200 are arranged on one side (left side) in the width direction of the substrate carrier 140, and five reactors 200 are arranged on the other side (right side) in the width direction. Note that, when the reactors 200 are individually designated, the reactors 200 on the left side are referred to as 200a, 200b, 200c, 200d, and 200e in order from the front, and the reactors 200 on the right side are referred to as 200f, 200g, 200h, 200i, and 200j in order from the front.

Further, the load port 110, the first container mover 120, the second container mover 180, the substrate carrier 140, and the reactor 200 are fixed to a floor 101.

Next, each configuration of the substrate processing apparatus 100 will be specifically described. Note that an operation of each part of the substrate processing apparatus 100 is controlled by a controller 400 as an example of a controller to be described below.

### (Load Port)

As illustrated in FIG. 1, the load port 110 is installed in front of (front side of) the substrate processing apparatus 100. A plurality of support tables 111 is provided on the load port 110. A storage container 102 as an example of a container is mounted on the support table 111. The storage container 102 is a container capable of storing the substrate S such as a silicon (Si) substrate. The storage container 102 may be referred to as a FOUP, a cassette, or the like.

### (First Container Mover)

As illustrated in FIG. 1, the first container mover 120 is adjacent to the load port 110 behind the load port 110. The first container mover 120 is adjacent to the reactor 200 on the opposite side of the load port 110. Specifically, the first container mover 120 is adjacent to the reactor 200a and the reactor 200f.

The first container mover 120 is configured to be able to move the storage container 102. Specifically, the first container mover 120 is a portion that moves (transfers) the storage container 102 between the load port 110, and the substrate carrier 140 and the third container mover 160. The first container mover 120 is also referred to as a front-side container mover or a front-side atmosphere transfer chamber.

The first container mover 120 includes a housing 121. An inside of the housing 121 is a transfer space 122 for carrying the storage container 102.

A loading/unloading port 112 for loading/unloading the storage container 102 into/from the housing 121 from/into the load port 110 is provided in the front side of the housing 121. The loading/unloading port 112 is opened and closed by a shutter 129.

A loading/unloading port t 128 for loading/unloading the storage container 102 from/into the inside of the housing 121 into/from a housing 141 of the substrate carrier 140 is provided in a lower portion on the rear side of the housing 121. The loading/unloading port 128 is provided with an opener 145 for opening a lid of the storage container 102. Note that the opener 145 is provided on the substrate carrier 140 side.

A loading/unloading port 126 for loading/unloading the storage container 102 from/into the inside of the housing 121 into/from an outside where the third container mover 160 is arranged is provided in an upper portion on the rear side of the housing 121.

Further, the first container mover 120 includes an elevator 123, a robot 124, a table 125 as an example of a first container table, and a table 127 as an example of a second container table. The robot 124 and the elevator 123 collectively constitute a front-side container carrier. The front-side container carrier is an example of a first container carrier in the present disclosure.

The elevator 123 is configured to be movable in the up-down direction. The robot 124 is mounted on the elevator 123. When the elevator 123 moves in the up-down direction, the robot 124 also moves in the up-down direction. Here, in a case where the robot 124 holds the storage container 102, the storage container 102 moves in the up-down direction together with the robot 124 by the movement of the elevator 123 in the up-down direction. Further, the elevator 123 is configured to be raised to a height at which the robot 124 can place the storage container 102 on the upper table 125 and receive the storage container 102 from the table 125. On the other hand, the elevator 123 is configured to be lowered to a height at which the robot 124 can place the storage container 102 on the lower table 127 and receive the storage container 102 from the table 127.

The robot 124 is mounted on the elevator 123 and has a function to hold the storage container 102. The robot 124 moves together with the elevator 123, and carries the storage container 102 between the support table 111, and the table 125 and the table 127. The robot 124 includes a fixture 124a fixed to the elevator 123, a rotator 124b provided on the fixture 124a, and a support 124c provided on the rotator 124b. The rotator 124b is rotatable about the up-down direction as an axis. The support 124c is a portion that supports the storage container 102. The support 124c rotates in a horizontal direction as the rotator 124b rotates. With this configuration, the storage container 102 can be carried between the support table 111, and the table 125 and the table 127.

The table 125 is a table that supports the storage container 102, and is adjacent to the third container mover 160. Specifically, the table 125 is a table arranged in the vicinity of the loading/unloading port 126, adjacent to the third container mover 160 via the loading/unloading port 126, and on which the storage container 102 is placed when the storage container 102 is transferred between the first container mover 120 and the third container mover 160 (at the time of transfer).

The table 127 is a table that supports the storage container 102, and is adjacent to the substrate carrier 140. Specifically, the table 127 is a table arranged in the vicinity of the loading/unloading port 128, adjacent to the substrate carrier 140 via the loading/unloading port 128, and on which the substrate S is placed when the substrate S in the storage container 102 is transferred between the first container mover 120 and the substrate carrier 140 (at the time of transfer).

Further, the storage container 102 is placed on the table 127 such that the lid of the storage container 102 faces the substrate carrier 140. In other words, the storage container 102 is arranged on the table 127 such that the lid faces rearward.

Further, the operation of each part of the first container mover 120 is controlled by the controller 400. As an example, the controller 400 can control the elevator 123 and the robot 124 to move the storage container 102 supported by the load port 110 to the table 125 or the table 127. That is, the elevator 123 and the robot 124 controlled by the controller 400 move the storage container 102 supported by the load port 110 to the table 125 or the table 127.

### (Second Container Mover)

As illustrated in FIG. 1, the second container mover 180 is adjacent to the reactor 200 behind the reactor 200. Specifically, the second container mover 180 is adjacent to the reactor 200e and the reactor 200j.

The second container mover 180 is arranged at a position different from that of the first container mover 120. Specifically, the second container mover 180 is arranged at a position facing the first container mover 120 in the front-rear direction, in other words, at a position behind the first container mover 120.

Further, the second container mover 180 is configured to be able to move the storage container 102. Specifically, the second container mover 180 is a portion that moves (transfers) the storage container 102 between the substrate carrier 140 and the third container mover 160. The second container mover 180 is also referred to as a rear-side container mover or a rear-side atmosphere transfer chamber.

The second container mover 180 includes a housing 181. An inside of the housing 181 is a transfer space 182 for carrying the storage container 102.

A loading/unloading port 147 for loading/unloading the storage container 102 from/into the inside of the housing 181 into/from a housing 141 of the substrate carrier 140 is provided in a lower portion on the front side of the housing 181. The loading/unloading port 147 is provided with an opener 146 for opening the lid of the storage container 102. The opener 146 is provided on the substrate carrier 140 side.

A loading/unloading port 163 for loading/unloading the storage container 102 from/into the inside of the housing 181 into/from the outside where the third container mover 160 is arranged is provided in an upper portion on the rear side of the housing 181.

Further, the second container mover 180 includes an elevator 183, a robot 184, a table 185 as an example of a third container table, and a table 186 as an example of a fourth container table. The robot 184 and the elevator 183 are collectively referred to as a rear-side container carrier. The rear-side container carrier is an example of a second container carrier in the present disclosure.

The elevator 183 is configured to be movable in the up-down direction. The robot 184 is mounted on the elevator 183. When the elevator 183 moves in the up-down direction, the robot 184 also moves in the up-down direction. Here, in a case where the robot 184 holds the storage container 102, the storage container 102 moves in the up-down direction together with the robot 184 by the movement of the elevator 183 in the up-down direction. Further, the elevator 183 is configured to be raised to a height at which the robot 184 can place the storage container 102 on the upper table 185 and receive the storage container 102 from the table 185. On the other hand, the elevator 183 is configured to be lowered to a height at which the robot 184 can place the storage container 102 on the lower table 186 and receive the storage container 102 from the table 186.

The robot 184 is mounted on the elevator 183 and has a function to hold the storage container 102. The robot 184 moves together with the elevator 183, and carries the storage container 102 between the support table 111, and the table 185 and the table 186. The robot 184 includes a fixture 184a fixed to the elevator 183, a rotator 184b provided on the fixture 184a, and a support 184c provided on the rotator 184b. The rotator 184b is rotatable about the up-down direction as an axis. The support 184c is a portion that supports the storage container 102. The support 184c rotates in the horizontal direction as the rotator 184b rotates. With this configuration, the storage container 102 can be carried between the support table 111, and the table 185 and the table 186.

The table 185 is a table that supports the storage container 102, and is adjacent to the third container mover 160. Specifically, the table 185 is a table arranged in the vicinity of the loading/unloading port 163, adjacent to the third container mover 160 via the loading/unloading port 163, and on which the storage container 102 is placed when the storage container 102 is transferred between the second container mover 180 and the third container mover 160 (at the time of transfer).

The table 186 is a table that supports the storage container 102, and is adjacent to the substrate carrier 140. Specifically, the table 186 is a table arranged in the vicinity of the loading/unloading port 147, adjacent to the substrate carrier 140 via the loading/unloading port 147, and on which the substrate S is placed when the substrate S in the storage container 102 is transferred between the second container mover 180 and the substrate carrier 140 (at the time of transfer).

Further, the storage container 102 is placed on the table 186 such that the lid of the storage container 102 faces the substrate carrier 140. In other words, the storage container 102 is arranged on the table 186 such that the lid faces forward. That is, the table 186 is configured such that the lid of the storage container 102 supported by the table 186 and the lid of the storage container 102 supported by the table 127 face each other.

The operation of each part of the second container mover 180 is controlled by the controller 400. As an example, the controller 400 moves the storage container 102 in the first container mover 120 to the second container mover 180 via the third container mover 160. Specifically, the storage container 102 supported by the table 125 is moved to the table 185 by the third container mover 160. Thereafter, the elevator 183 and the robot 184 are controlled so that the storage container 102 supported by the table 185 is supported by the table 186.

### (Substrate Carrier)

As illustrated in FIG. 1, the substrate carrier 140 is arranged between the first container mover 120 and the second container mover 180 and on the lower side. The plurality of reactors 200 is arranged on both sides of the substrate carrier 140 in the width direction. The substrate carrier 140 is configured to be communicable with the plurality of reactors 200. The substrate carrier 140 is a portion that carries the storage container 102 between the first container mover 120 and each reactor 200, and carries the storage container 102 between the second container mover 180 and each reactor 200. The substrate carrier 140 is also referred to as a lower transfer chamber.

The substrate carrier 140 includes the housing 141. An inside of the housing 141 is a transfer space 142 for carrying the storage container 102.

The loading/unloading port 128 is provided in the front side of the housing 141, and the opener 145 is provided near the loading/unloading port 128.

The loading/unloading port 147 is provided in the rear side of the housing 141, and the opener 146 is provided near the loading/unloading port 147.

A carry robot 144 to be described below moves in the housing 141. A rail 143 is provided. Specifically, the rail 143 is provided at a lower portion of the housing 141 and extends in the front-rear direction. In other words, the rail 143 extends from the loading/unloading port 128 toward the loading/unloading port 147 or from the loading/unloading port 147 toward the loading/unloading port 128.

The substrate carrier 140 is provided with the carry robot 144 as an example of a substrate carry robot capable of carrying the substrate S to each reactor 200. In other words, the substrate carrier 140 includes the carry robot 144 in the housing 141. Further, in the present embodiment, the substrate carrier 140 includes a plurality of the carry robots 144.

The carry robot 144 is movable along the rail 143 on the rail 143. The carry robot 144 is configured to be able to mount a plurality of the substrates S. That is, the carry robot 144 can move on the rail 143 in a state of mounting (holding) the plurality of substrates S to carry the substrates S to the target reactor 200.

Further, in the present embodiment, the substrate carrier 140 includes the plurality of carry robots 144. A corresponding reactor 200 is set in each of the plurality of carry robots 144. Specifically, the substrate carrier 140 includes the two carry robots 144, and one carry robot 144 is provided in front of the other carry robot 144 on the rail 143. Hereinafter, the carry robot 144 disposed on the front side is referred to as a front-side carry robot 144a, and the carry robot 144 disposed on the rear side is referred to as a rear-side carry robot 144b. The front-side carry robot 144a of the present embodiment is an example of a first substrate carry robot in the present disclosure, and the rear-side carry robot 144b of the present embodiment is an example of a second substrate carry robot in the present disclosure.

The front-side carry robot 144a of the present embodiment is in charge of the reactors 200 arranged on the front side among the plurality of reactors 200. Specifically, the front-side carry robot 144a is in charge of the reactor 200a, the reactor 200b, the reactor 200f, and the reactor 200g. Note that, in the present embodiment, since five reactors 200 are arranged on each side, the front-side carry robot 144a is also in charge of the reactor 200c and the reactor 200h located in the center in the front-rear direction. In other words, the front-side carry robot 144a carries the substrate S to the reactor 200a, the reactor 200b, the reactor 200c, the reactor 200f, the reactor 200g, and the reactor 200h.

The rear-side carry robot 144b of the present embodiment is in charge of the reactors 200 arranged on the rear side among the plurality of reactors 200. Specifically, the rear-side carry robot 144b is in charge of the reactor 200d, the reactor 200e, the reactor 200i, and the reactor 200j. In other words, the rear-side carry robot 144b carries the substrate S to the reactor 200d, the reactor 200e, the reactor 200i, and the reactor 200j.

Further, in a case where the plurality of reactors 200 can perform different substrate processing, transfer areas (the reactors 200 in charge) of the front-side carry robot 144a and the rear-side carry robot 144b may be set according to types of the substrate processing by the reactors 200.

Furthermore, the transfer areas (the reactors 200 in charge) of the front-side carry robot 144a and the rear-side carry robot 144b may be set according to a time of the substrate processing by the reactor 200.

Furthermore, in the case where the plurality of reactors 200 can perform different substrate processing, the carry robot 144 may be set to move to a different reactor (another reactor) 200 after processing the substrate S in a certain reactor 200.

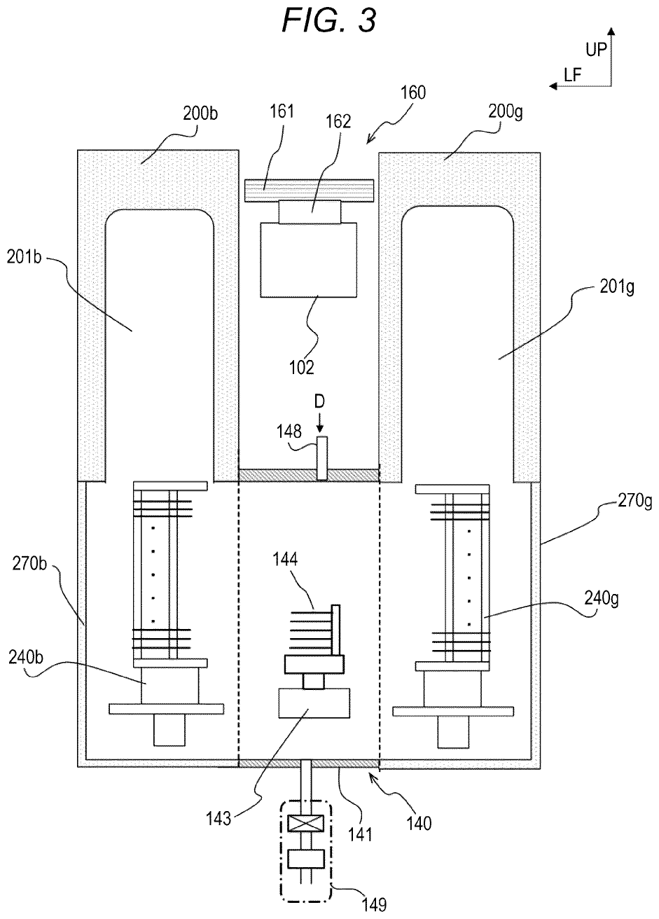

Further, as illustrated in FIG. 3, the substrate carrier 140 includes an inert gas supplier 148 and an exhauster 149. The inert gas supplier 148 is configured to supply an inert gas into the housing 141. When the inert gas is supplied into the housing 141, the transfer space 142 becomes an inert gas atmosphere. The exhauster 149 is a portion that exhausts the atmosphere in the housing 141.

The operation of each part of the substrate carrier 140 is controlled by the controller 400. As an example, the controller 400 sets the transfer areas (the reactors 200 in charge) of the plurality of carry robots 144.

### (Third Container Mover)

As illustrated in FIG. 1, the third container mover 160 is disposed between the first container mover 120 and the second container mover 180 and on the upper side. The plurality of reactors 200 is arranged on both sides of the third container mover 160 in the width direction. The third container mover 160 is a part that can move the storage container 102 from the first container mover 120 to the second container mover 180. That is, the third container mover 160 is a portion that can move (carry) the storage container 102 between the first container mover 120 and the second container mover 180. Therefore, the third container mover 160 is also referred to as an upper carrier.

The third container mover 160 includes a rail 161 and a container carrier 162.

The rail 161 is stretched between the first container mover 120 and the second container mover 180. Specifically, the rail 161 extends from the upper side of the loading/unloading port 126 of the housing 121 toward the upper side of the loading/unloading port 163 of the housing 181. The container carrier 162 moves along the rail 161.

The container carrier 162 holds and carries the storage container 102. The container carrier 162 moves along the rail 161 as described above. That is, the container carrier 162 makes the storage container 102 movable (carriable) between the first container mover 120 and the second container mover 180 by moving on the rail 161 in a state of holding the storage container 102.

Further, the third container mover 160 is configured to be able to carry the storage container 102 in an atmosphere independent of the substrate carrier 140. Here, the substrate carrier 140 in the present embodiment carries the substrate S under the inert gas atmosphere, but the third container mover 160 carries the substrate S in the atmosphere, and thus the atmospheres for carrying the storage containers 102 in both spaces are different. That is, the atmosphere of the third container mover 160 is independent of the atmosphere of the substrate carrier 140.

Further, the container carrier 162 may be provided with a rotator. The rotator is a portion that rotates in the horizontal direction about the up-down direction as an axial direction. By rotating the rotator, the storage container 102 held by the container carrier 162 can be rotated in the horizontal direction. Accordingly, the direction of the lid of the storage container 102 can be changed.

### (Reactor: Batch Apparatus)

As illustrated in FIG. 2, the plurality of reactors 200 is arranged on both sides of the substrate carrier 140 in the width direction. The reactor 200 is an apparatus capable of processing the substrate S in the storage container 102. Since the reactors 200 have similar configurations, one reactor 200 will be described here. Each reactor 200 is configured to be able to perform a plurality of processes. Details will be described below.

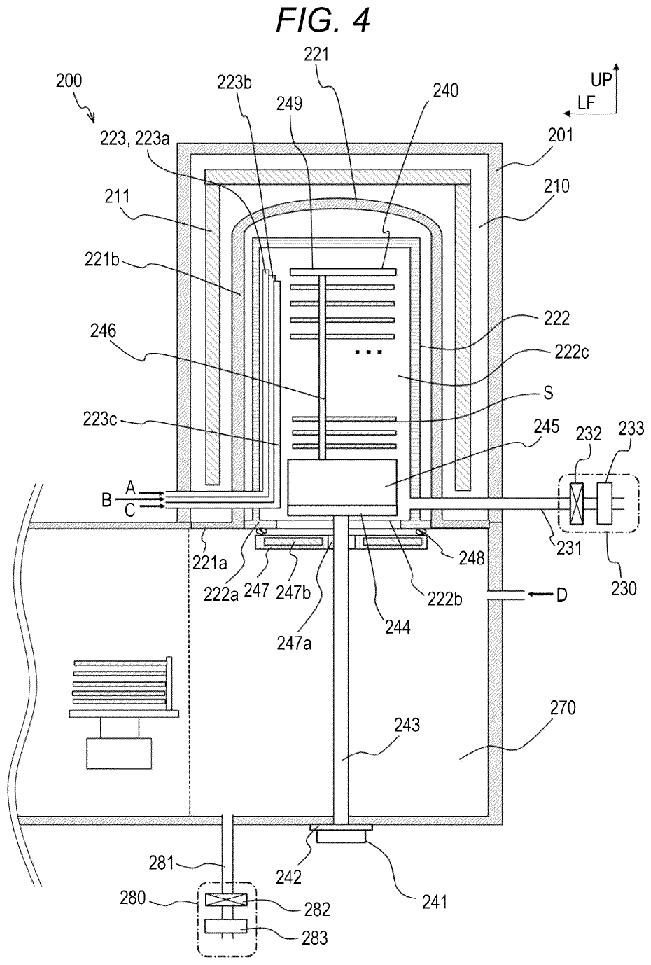

As illustrated in FIG. 4, a housing 201 constituting the reactor 200 includes a reaction tube storage chamber 210 on the upper side and a transfer chamber 270 on the lower side. A heater 211 and an inner reaction tube 222 are mainly stored in the reaction tube storage chamber 210. The transfer chamber 270 communicates with the inside of the housing 141 of the substrate carrier 140.

The transfer chamber 270 is installed in a lower portion of the inner reaction tube 222 and is configured to communicate with the inner reaction tube 222. In the transfer chamber 270, the carry robot 144 places (mounts) the substrate S on a substrate support tool (hereinafter may be referred to as a boat) 240 to be described below, and the carry robot 144 takes out the substrate S from the substrate support tool 240.

Subsequently, the reaction tube storage chamber 210 and the inner reaction tube 222 stored therein will be described. The inner reaction tube 222 includes an outer reaction tube 221 and the inner reaction tube 222. The inner reaction tube 222 is housed inside the outer reaction tube 221.

The outer reaction tube 221 is provided between the inner reaction tube 222 and the heater 211. In FIG. 4, the atmosphere in the outer reaction tube 221 and the atmosphere in the inner reaction tube 222 are partitioned from each other. In the outer reaction tube 221, a chamber in which the inner reaction tube 222 is stored is referred to as an inner reaction tube storage chamber 221b.

A flange 221a is provided in a lower portion of the outer reaction tube 221. A hole is provided in a center of the flange 221a, and a flange 222a of the inner reaction tube 222 is inserted into and fixed to the hole. The flange 221a and the flange 222a are collectively referred to as a furnace opening 222b.

An upper portion of the inner reaction tube 222 is closed, and the flange 222a is provided in a lower portion The furnace opening 222b through which the substrate support tool 240 passes is provided in the center of the flange 222a.

The inner reaction tube 222 can accommodate the substrate S supported by the substrate support tool 240. The inner reaction tube 222 is provided with a nozzle 223 serving as a gas supplier. The nozzle 223 is configured to extend in a vertical direction that is an arrangement direction of the plurality of substrates S. The gas supplied through the nozzle 223 is supplied to each substrate S.

The nozzle 223 is provided for each gas type, for example, and here, three nozzles 223a, 223b, and 223c are illustrated as an example. The nozzles 223 are disposed so as not to overlap each other in the horizontal direction. Note that FIG. 4 illustrates the three nozzles 223 for convenience of description, but the present embodiment is not limited thereto, and four or more nozzles or two or less nozzles may be arranged according to the content of the substrate processing.

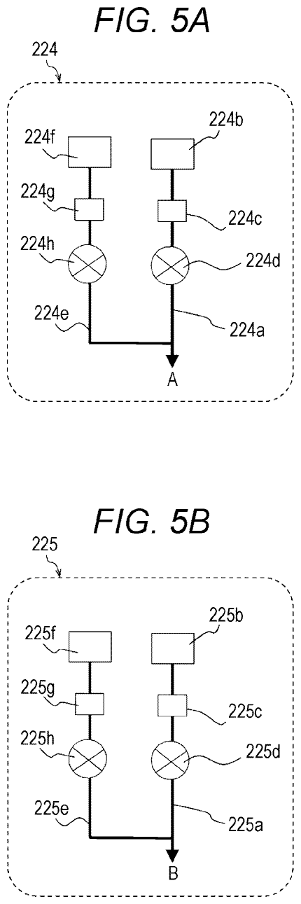

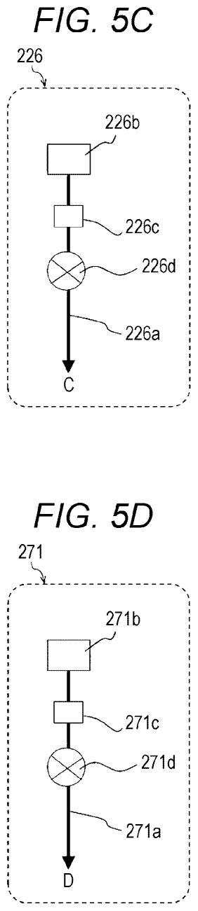

Next, a gas supplier capable of supplying gas to each nozzle 223 will be described with reference to FIGS. 5A, 5B, 5C, and 5D. In the present disclosure, for example, a first gas supplier and a second gas supplier to be described below are collectively referred to as a gas supplier.

First, a first gas supplier 224 capable of supplying gas to the nozzle 223a will be described with reference to FIG. 5A. A gas supply pipe 224a is provided with a first gas source 224b, a mass flow controller (MFC) 224c serving as a flow rate controller, and a valve 224d serving as an on-off valve in this order from an upstream direction. The gas supply pipe 224a is configured to communicate with the nozzle 223a.

The first gas source 224b is a first gas (also referred to as “first element-containing gas”) source containing a first element. The first element-containing gas is one of source gases, that is, a processing gas. Here, the first element is, for example, silicon (Si). Specifically, the first element-containing gas is a chlorosilane source gas containing a Si—Cl bond, such hexachlorodisilane (Si₂Cl₆, abbreviation: HCDS) gas, monochlorosilane (SiH₃Cl, abbreviation: MCS) gas, dichlorosilane (SiH₂Cl₂, abbreviation: DCS), trichlorosilane (SiHCl₃, abbreviation: TCS) gas, tetrachlorosilane (SiCl₄, abbreviation: STC) gas, or octachlorotrisilane (Si₃Cl₈, abbreviation: OCTS) gas.

The gas supply pipe 224a, the MFC 224c, and the valve 224d mainly constitute the first gas supplier (also referred to as a silicon-containing gas supplier) 224.

A gas supply pipe 224e is connected to a downstream side of the valve 224d in the gas supply pipe 224a. The gas supply pipe 224e is provided with an inert gas source 224f, an MFC 224g, and a valve 224h in this order from the upstream direction. An inert gas, for example, nitrogen (N₂) gas is supplied from the inert gas source 224f.

The gas supply pipe 224e, the MFC 224g, and the valve 224h mainly constitute a first inert gas supplier. The inert gas supplied from the inert gas source 224f is used as a carrier gas or a dilution gas of the first gas in a substrate processing step. The first inert gas supplier may be added to the first gas supplier.

Next, a second gas supplier 225 capable of supplying gas to the nozzle 223b will be described with reference to FIG. 5B. A gas supply pipe 225a includes a second gas source 225b, an MFC 225c, and a valve 225d in this order from the upstream direction. The gas supply pipe 225a is configured to communicate with the nozzle 223b.

The second gas source 225b is a second gas (hereinafter, also referred to as “second element-containing gas”) source containing a second element. The second element-containing gas is one of the processing gases. The second element-containing gas may be considered as reactant gas or a modifying gas.

Here, the second element-containing gas contains the second element different from the first element. The second element is, for example, any one of oxygen (O), nitrogen (N), and carbon (C). In the present embodiment, the second element-containing gas is, for example, a nitrogen-containing gas. Specifically, the second element-containing gas is a hydrogen nitride-based gas containing an N—H bond, such as ammonia (NH₃), diazene (N₂H₂) gas, hydrazine (N₂H₄) gas, or N₃H₈ gas.

The gas supply pipe 225a, the MFC 225c, and the valve 225d mainly constitute the second gas supplier (also referred to as a reactant gas supplier) 225.

A gas supply pipe 225e is connected to a downstream side of the valve 225d in the gas supply pipe 225a. The gas supply pipe 225e is provided with an inert gas source 225f, an MFC 225g, and a valve 225h in this order from the upstream direction. An inert gas is supplied from the inert gas source 225f.

The gas supply pipe 225e, the MFC 225g, and the valve 225h mainly constitute a second inert gas supplier. The inert gas supplied from the inert gas source 225f is used as a carrier gas or a dilution gas of the second gas in the substrate processing step. The second inert gas supplier may be added to the second gas supplier 225.

Next, an inert gas supplier 226 capable of supplying gas to the nozzle 223c will be described with reference to FIG. 5C. A gas supply pipe 226a includes an inert gas source 226b, an MFC 226c, and a valve 226d in this order from the upstream direction. The inert gas supplied from the inert gas source 226b is used as, for example, a purge gas for purging the atmosphere in the inner reaction tube 222 or a pressure regulating gas for regulating pressure of the inner reaction tube 222. The gas supply pipe 226a is configured to communicate with the nozzle 223c.

An exhauster 230 that exhausts the atmosphere in the inner reaction tube 222 includes an exhaust pipe 231 communicating with the inner reaction tube 222.

A vacuum pump (not illustrated) serving as a vacuum exhaust device is connected to the exhaust pipe 231 through a valve 232 serving as an on-off valve and an auto pressure controller (APC) valve 233 serving as a pressure regulator, and is configured to be able to perform vacuum exhaust such that the pressure in the inner reaction tube 222 fulfills a predetermined pressure (a predetermined degree of vacuum).

The pressure in the inner reaction tube 222 is regulated by cooperation of the above-described gas supplier and exhauster. When the pressure is regulated, a pressure value detected by a pressure detector (not illustrated) is regulated to a predetermined value.

In the inner reaction tube 222, a region in which the substrate S is stored is referred to as a processing region, and a section constituting the processing region is referred to as a process chamber 222c. In the present embodiment, the inner reaction tube 222 constitutes the process chamber 222c.

The substrate support tool 240 transfers the substrate S inside the transfer chamber 270 carried by the carry robot 144 through the loading/unloading port 147. Further, the substrate support tool 240 carries the transferred substrate S to the inside of the inner reaction tube 222. Then, processing such as forming a thin film on a surface of the substrate S is performed inside the inner reaction tube 222.

The substrate support tool 240 includes a lift 241 that drives the substrate support tool 240 in the up-down direction. FIG. 4 illustrates a state in which the substrate support tool 240 is raised by the lift 241 and stored in the inner reaction tube 222. In addition, the substrate support tool 240 includes a rotation driver 242 that drives the substrate support tool 240 to rotate.

Each driver is connected to a shaft 243 that supports a support table 244. The support table 244 is provided with a plurality of support columns 246 capable of supporting the substrate S. The support column 246 supports a top plate 249. FIG. 4 illustrates one support column 246 for convenience of description. The support column 246 is provided with a plurality of substrate support mechanisms at predetermined intervals in the vertical direction, and the plurality of substrates S are supported by the respective substrate support mechanisms. A lower portion of the plurality of support columns 246 is covered with a heat insulating cover 245.

The substrate support tool 240 supports a plurality of, for example, five substrates S in multiple stages in the vertical direction with the plurality of support columns 246. The top plate 249 and the plurality of support columns 246 are made of a material such as quartz or Sic, for example. Note that, here, an example in which seven substrates S are supported by the substrate support tool 240 is illustrated, but the present embodiment is not limited thereto. For example, the substrate support tool 240 may be configured to support about five to fifty substrates S.

The substrate support tool 240 is moved in the up-down direction between the inner reaction tube 222 and the transfer chamber 270 by the lift 241, and is driven by the rotation driver 242b in a rotation direction around a center of the substrate S supported by the substrate support tool 240.

A lid body 247 that closes the furnace opening 222b is fixed to the shaft 243 via a fixture 247a. A diameter of the lid body 247 is configured to be larger than a diameter of the furnace opening 222b. The lid body 247 is provided with a heater 247b that heats the lid body 247. The flange 222a of the inner reaction tube 222 is provided with an O-ring 248 as a sealing member.

The lid body 247 closes the furnace opening 222b, for example, while the substrate S is processed. When the lid body 247 closes the furnace opening 222b, the lift 241 raises the lid body 247 so that an upper surface of the lid body 247 is set at a position to be pressed against the flange 222a, as illustrated in FIG. 4. Accordingly, the inside of the inner reaction tube 222 can be kept airtight.

The transfer chamber 270 is installed under the reaction tube storage chamber 210. In the transfer chamber 270, the carry robot 144 places (mounts) the substrate S on the substrate support tool 240 via the loading/unloading port 147, and the carry robot 144 takes out the substrate S from the substrate support tool 240.

The transfer chamber 270 is provided with an exhauster 280 that exhausts the atmosphere in the transfer chamber 270. The exhauster 280 has an exhaust pipe 281 connected to the transfer chamber 270 and communicating with the inside thereof.

A vacuum pump (not illustrated) serving as a vacuum exhaust device is connected to the exhaust pipe 281 via a valve 282 serving as an on-off valve and an APC valve 283, and is configured to be able to perform exhaust so that the pressure in the transfer chamber 270 becomes a predetermined pressure.

An inert gas supplier 271 illustrated in FIG. 5D may be connected to the transfer chamber 270. As illustrated in FIG. 5D, a gas supply pipe 271a includes an inert gas source 271b, an MFC 271c, and a valve 271d in this order from the upstream direction. The inert gas supplied from the inert gas source 271b is used, for example, to purge the atmosphere in the transfer chamber 270 or to regulate the pressure. The inert gas supplier 271 is also referred to as a third gas supplier.

### (Controller)

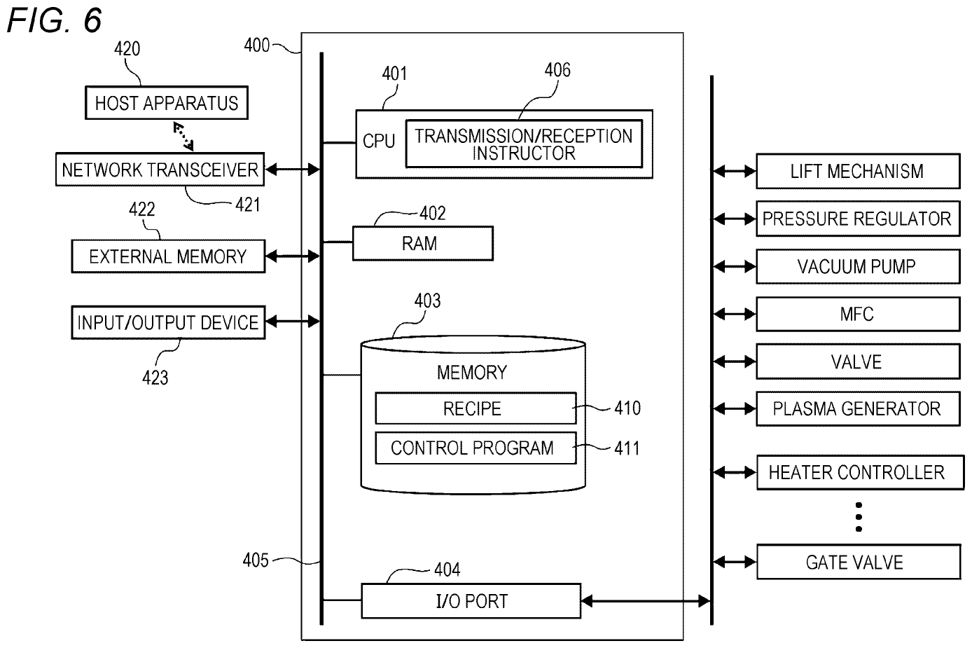

Next, the controller 400 as an example of a controller will be described with reference to FIG. 6. The substrate processing apparatus 100 includes the controller 400 that controls the operation of each part.

The controller 400 is formed as a computer including a central processing unit (CPU) 401, a random access memory (RAM) 402, a memory 403, and an I/O port 404. The RAM 402, the memory 403, and the I/O port 404 are configured to be able to exchange data with the CPU 401 via an internal bus 405. Transmission/reception of data in the substrate processing apparatus 100 is performed on the basis of an instruction from a transmission/reception instructor 406 that is one function of the CPU 401.

The CPU 401 is configured to read and execute a control program from the memory 403, and to read a process recipe from the memory 403 in response to an input of an operation command from an input/output device 423 or the like. Then, the CPU 401 is configured to be able to control, for example, lifting operation of each lift mechanism, substrate transfer operation by the robot, on/off control of each pump, flow rate regulating operation of the MFC, opening/closing operation of the valve, and the like in accordance with content of the read process recipe.

The memory 403 includes, for example, a flash memory and a hard disk drive (HDD). In the memory 403, a recipe 410 including a process recipe or the like in which a procedure, a condition, and the like of substrate processing are described, and a control program 411 for controlling the operation of the substrate processing apparatus are readably stored.

Note that the process recipe functions as a program for causing the controller 400 to execute each procedure in the substrate processing step to be described below to obtain a predetermined result. This process recipe exists, for example, for each reactor and is read out for each reactor.

Hereinafter, for example, the process recipe, the control program, and the like will also be collectively and simply referred to as a program. Note that the term “program” in the present specification may include only the process recipe, may include only the control program, or may include both thereof. Further, the RAM 402 serves as a memory area (work area) in which the program or data read by the CPU 401 is temporarily stored.

The I/O port 404 is connected to each configuration such as each pressure regulator, each pump, and a heater controller. Furthermore, a network transceiver 421 connected to a host apparatus 420 via a network is provided.

For example, the controller 400 according to this technology can be configured by installing a program in a computer using an external memory 422 that stores the above-described program. Note that examples of the external memory 422 include a magnetic disk such as a hard disk, an optical disk such as a DVD, a magneto-optical disk such as an MO, and a semiconductor memory such as a USB memory. Further, supply of the program to a computer is not limited to the case via the external memory 422. For example, the program may be supplied using a communicator such as the Internet or a dedicated line without using the external memory 422. Note that the memory 403 and the external memory 422 are configured as a computer-readable recording medium. Hereinafter, the memory and the external memory will also be collectively and simply referred to as recording media. Note that, herein, the term “recording medium” in the present specification may include only the memory 403, may include only the external memory 422, or may include both thereof.

### (2) Substrate Processing Step

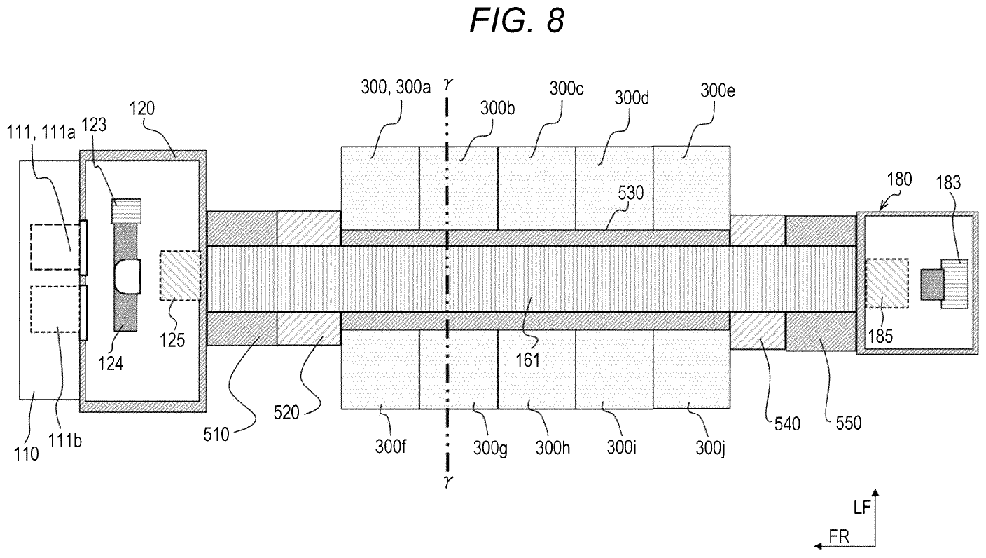

Next, the substrate processing step will be described with reference to FIG. 8. Next, as one step of the substrate processing apparatus, a step of processing the substrate S using the substrate processing apparatus 100 having the above-described configuration will be described. Note that in the following description, operation of each part constituting the substrate processing apparatus is controlled by the controller 400.

### [Container Moving Step]

A container moving step will be described.

First, the substrate processing apparatus 100 receives the storage container 102 supported by the support table 111 of the load port 110 by the robot 124 of the first container mover 120. As a result, the storage container 102 moves from the load port 110 to the first container mover 120.

Next, the substrate processing apparatus 100 carries the substrate S stored in the storage container 102 from the first container mover 120 to the transfer target reactor 200 via the substrate carrier 140. Specifically, the storage container 102 (substrate S) is sent toward the carry robot 144 in charge of the transfer target reactor 200, and the substrate S is carried from the carry robot 144 to the reactor 200.

For example, in a case where the front-side carry robot 144a is in charge of the transfer target reactor 200, the storage container 102 is placed on the table 127 using the robot 124 and the elevator 123. Next, the lid of the storage container 102 is opened by the opener 145. Then, the front-side carry robot 144a takes out the substrate S from the storage container 102 and carries the substrate S to the transfer target reactor 200. Thereafter, the front-side carry robot 144a transfers the substrate S to the substrate support tool 240 of the transfer target reactor 200. That is, in the case where the front-side carry robot 144a is in charge of the transfer target reactor 200, the substrate S is loaded into the transfer target reactor 200 via the first container mover 120 and the substrate carrier 140.

Meanwhile, in a case where the rear-side carry robot 144b is in charge of the transfer target reactor 200, the storage container 102 is placed on the table 125 using the robot 124 and the elevator 123. Next, the storage container 102 supported by the table 125 is placed on the table 185 of the second container mover 180 by the container carrier 162 of the third container mover 160. Next, the storage container 102 is moved from the table 185 to the table 186 using the robot 184 and the elevator 183. Next, the lid of the storage container 102 is opened by the opener 146. Then, the rear-side carry robot 144b takes out the substrate S from the storage container 102 and carries the substrate S to the transfer target reactor 200. Thereafter, the rear-side carry robot 144b transfers the substrate S to the substrate support tool 240 of the transfer target reactor 200. That is, in the case where the rear-side carry robot 144b is in charge of the transfer target reactor 200, the substrate S is loaded into the transfer target reactor 200 via the first container mover 120, the third container mover 160, the second container mover 180, and the substrate carrier 140. Note that, in the present embodiment, when the substrate S is loaded into the substrate carrier 140, the inert gas supplier 148 and the exhauster 149 are regulated so that the atmosphere of the substrate carrier 140 becomes an inert gas atmosphere.

### [Substrate Loading Step]

Next, the substrate loading step will be described. In the substrate loading step, the substrate support tool 240 supporting the substrate S is raised and loaded into the inner reaction tube 222 as illustrated in FIG. 4. At this time, the lid body 247 rises together with the substrate support tool 240, and the O-ring 248 is pressed against the lid body 247. Accordingly, the inside of the inner reaction tube 222 is sealed. Note that the heater 211 is in an operating state and is maintained at a processing temperature of the substrate S.

Subsequently, the inside of the inner reaction tube 222 is brought to a predetermined pressure by the cooperation of the inert gas supplier 226 and the exhauster 230. In parallel with this, the inert gas supplier 271 and the exhauster 280 are controlled so that the pressure in the transfer chamber 270 becomes higher than the pressure in the inner reaction tube 222. In this way, it is possible to suppress the atmosphere in the inner reaction tube 222 from moving to the transfer chamber 270.

### [Film Processing Step]

Next, a film processing step will be described. The film processing step is a step of processing a film formed on the substrate S in the reactor 200. When the process chamber 222c constituted by the inner reaction tube 222 has a desired pressure, the first gas supplier 224 and the second gas supplier 225 are controlled to supply the first gas and the second gas into the inner reaction tube 222 to process the substrate S. The processing in this step refers to, for example, processing of causing the first gas to react with the second gas to form a predetermined film on the substrate S. In the present embodiment, for example, HCDS is supplied as the first gas and NH₃ gas is supplied as the second gas to form a silicon nitride (SiN) film.

In the present step, for example, processing is performed under the following conditions.
The first gas: HCDS
A gas supply amount of the first gas 5 sccm to 5000 sccm
The second gas: NH₃
A gas supply amount of the second gas 10 sccm to 10000 sccm
The pressure in the process chamber: 133 Pa to 13332 Pa
Processing temperature: 300° C. to 500° C.

When a predetermined time has elapsed, the first gas supplier 224 and the second gas supplier 225 are stopped. Further, the inert gas is supplied from the inert gas supplier 226 to exhaust the atmosphere in the process chamber 222c.

### [Substrate Unloading Step]

A substrate unloading step will be described. After a lapse of a predetermined time, the lift 241 lowers the substrate support tool 240. When the substrate support tool 240 is lowered, the substrate S is unloaded by a method reverse to the method of loading the substrate S.

Next, effects of the present embodiment will be described.

The substrate processing apparatus 100 according to the present embodiment includes the third container mover 160 that carries the storage container 102 between the first container mover 120 and the second container mover 180. Therefore, in the substrate processing apparatus 100, the substrate S is carried to the second container mover 180 by the third container mover 160 in the state where the substrate S is stored in the storage container 102 (the state of the storage container 102). As a result, the substrate processing apparatus 100 can increase throughput, for example, as compared with a configuration in which the substrate S is carried from the first container mover 120 to the second container mover 180 in the state of the substrate S. To carry the substrate S in the state of the substrate S by the third container mover 160, the substrate S needs to be carried in the inert gas atmosphere, which increases a maintenance frequency and a component cost. In contrast, in the present embodiment, since the storage container 102 in which the substrate S is stored is carried to the second container mover 180 in the state of the storage container 102 by the third container mover 160, the cost can be reduced.

That is, the substrate processing apparatus 100 according to the present embodiment can achieve cost reduction and throughput improvement.

Further, in the substrate processing apparatus 100 according to the present embodiment, since a plurality of carry routes of the storage container 102 is provided, it is possible to carry different types of substrates while avoiding contamination (for example, a phenomenon in which a component of a substrate adheres to another substrate).

The substrate processing apparatus 100 according to the present embodiment can place the storage container 102 received by the load port 110 on the table 125 and the table 127. That is, in the substrate processing apparatus 100, since the storage container 102 can be directly carried from the load port 110 to the table 125 and the table 127, transfer efficiency of the substrate S can be enhanced. Further, since the elevator 123 is used, it is possible to suppress an increase in footprint.

In the substrate processing apparatus 100 according to the present embodiment, the controller 400 can control the elevator 123 and the robot 124 to move the storage container 102 supported by the load port 110 to the table 125 or the table 127.

In the substrate processing apparatus 100 according to the present embodiment, since the storage container 102 received from the third container mover 160 can be directly carried to the table 185 and the table 186, the transfer efficiency of the substrate S can be enhanced. Further, since the elevator 183 is used, it is possible to suppress an increase in footprint.

In the substrate processing apparatus 100 according to the present embodiment, the third container mover 160 can carry the storage container 102 in the atmosphere independent of the substrate carrier 140. Therefore, in the substrate processing apparatus 100, the third container mover 160 and the substrate carrier 140 are brought in the independent atmospheres, so that it is not necessary to provide a pressure-reducing structure such as the substrate carrier 140 in the third container mover 160, which leads to reduction in the number of components.

In the substrate processing apparatus 100 according to the present embodiment, the robot 124 of the first container mover 120 places the storage container 102 on the table 127 such that the lid of the storage container 102 faces the substrate carrier 140. Then, the robot 184 of the second container mover 180 places the storage container 102 on the table 186 such that the lid of the storage container 102 faces the substrate carrier 140. In other words, the lid of the storage container 102 placed on the table 127 and the lid of the storage container 102 placed on the table 186 face each other. For this reason, in the substrate processing apparatus 100, since the carry robot 144 of the substrate carrier 140 can receive the substrate S, the transfer efficiency of the substrate S is increased.

In the substrate processing apparatus 100 according to the present embodiment, in the case where the third container mover 160 is provided with the rotator, the first container mover 120 and the second container mover 180 can have a simple configuration, so that the maintenance frequency is reduced.

In the substrate processing apparatus 100 according to the present embodiment, the substrate carrier 140 includes the plurality of carry robots 144, and process modules that the respective carry robots are in charge of are set. As described above, in the substrate processing apparatus 100, it is possible to suppress contamination by setting the process module that the carry robot 144 is in charge of.

In the substrate processing apparatus 100 according to the present embodiment, in the case where the front-side carry robot 144a is in charge of the reactors 200 arranged on the front side and the rear-side carry robot 144b is in charge of the reactors 200 arranged on the rear side, a dedicated route and a dedicated robot for each process can be set, and thus contamination can be further suppressed.

In the substrate processing apparatus 100 according to the present embodiment, in the case where the plurality of reactors 200 can perform different substrate processing, the transfer areas of the front-side carry robot 144a and the rear-side carry robot 144b may be set according to the type of the substrate processing. In this case, since contamination can be suppressed as a transfer space (transfer area), it is possible to more reliably suppress the contamination.

In the substrate processing apparatus 100 according to the present embodiment, the transfer areas of the front-side carry robot 144a and the rear-side carry robot 144b may be set according to the time of the substrate processing. Here, if the process time is different, standby of the carry robot 144 occurs (for example, in a case where the substrate S cannot be loaded in because the reactor 200 as a load-in destination is crowded), and thus the transfer efficiency may be lowered. In contrast, in the substrate processing apparatus 100, the standby of the carry robot 144 can be eliminated by setting the transfer area in accordance with the processing time.

In the substrate processing apparatus 100 according to the present embodiment, the plurality of carry robots 144 move on the rail 143. Here, by arranging the plurality of carry robots 144 on the rail 143, smooth transfer becomes possible, and as a result, even in the case of moving a long distance, stable transfer becomes possible without sliding the substrate S.

In the substrate processing apparatus 100 according to the present embodiment, each of the plurality of reactors 200 can perform different processing, and in the case where the carry robot 144 moves to a different reactor 200 after processing in a certain reactor 200, continuous processing can be implemented. Specifically, for example, an SiN film may be formed in the certain reactor 200, and then modification processing may be performed in another process module.

### Second Embodiment

Next, a substrate processing apparatus 600 according to a second embodiment of the present disclosure will be described.

The substrate processing apparatus 600 of the present embodiment has a similar configuration to the substrate processing apparatus 100 of the first embodiment except for configurations of a substrate carrier 500 and a reactor 300. Therefore, in the present embodiment, the configurations of the substrate carrier 500 and the reactor 300 will be mainly described. Description of similar configurations to those of the substrate processing apparatus 100 of the first embodiment will be omitted.

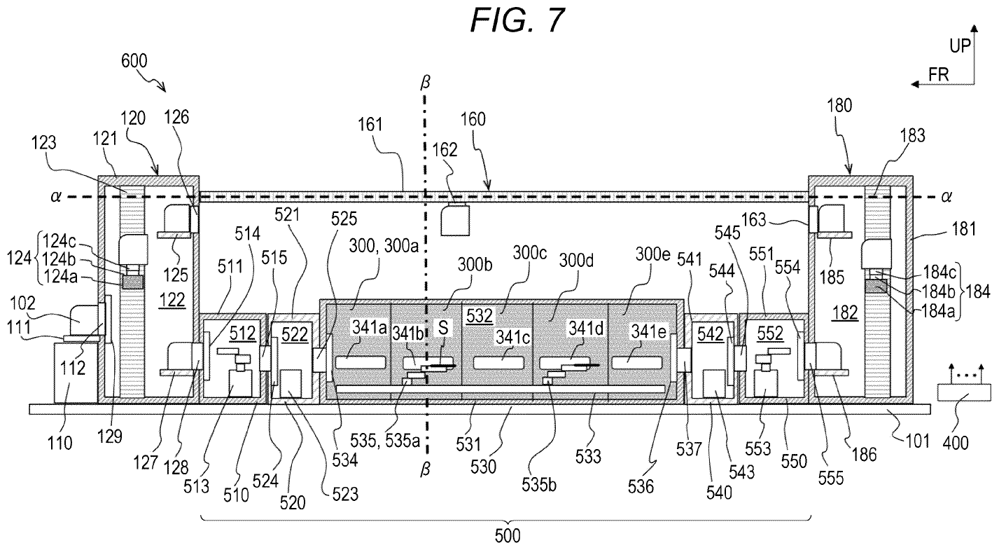

FIG. 7 is a transverse cross-sectional view illustrating a configuration example of the substrate processing apparatus according to the second embodiment of the present disclosure. FIG. 8 illustrates a configuration example of the substrate processing apparatus according to the second embodiment of the present disclosure, and is a longitudinal cross-sectional view taken along line α-α in FIG. 7.

### (Substrate Carrier)

As illustrated in FIG. 7, the substrate carrier 500 is arranged between a first container mover 120 and ae second container mover 180 and on a lower side. The substrate carrier 500 is a portion that carries a storage container 102 between the first container mover 120 and each reactor 300, and carries the storage container 102 between the second container mover 180 and each reactor 300. The substrate carrier 500 is also referred to as a lower transfer chamber.

The substrate carrier 500 includes an atmospheric carrier 510, a load lock chamber 520, a vacuum carrier 530, a load lock chamber 540, and an atmospheric carrier 550 in this order from the front.

### —Front-Side Atmospheric Carrier—

The atmospheric carrier 510 includes a housing 511. An inside of the housing 511 is a transfer space 512 for carrying the storage container 102. Note that the atmospheric carrier 510 of the present embodiment is also referred to as a front-side atmospheric carrier.

A loading/unloading port 128 is provided in a front side of the housing 511, and an opener 514 is provided near the loading/unloading port 128.

A loading/unloading port 515 for loading/unloading a substrate S taken out from the storage container 102 from/into the housing 511 into/from a housing 521 of the load lock chamber 520 is provided in a rear side of the housing 511. The loading/unloading port 515 is provided with a gate valve 524. The gate valve 524 is provided on the load lock chamber 520 side.

The atmospheric carrier 510 includes an atmospheric carry robot 513 in the housing 511. The atmospheric carry robot 513 takes out the substrate S from the storage container 102 on a table 127, and places the substrate S on a substrate placing table 523 of the load lock chamber 520. The atmospheric carry robot 513 can also return the substrate S from the substrate placing table 523 to the storage container 102. That is, the atmospheric carry robot 513 can carry the substrate S between the first container mover 120 and the load lock chamber 520.

### —Front-Side Load Lock Chamber—

The load lock chamber 520 includes the housing 521. An inside of the housing 521 is a transfer space 522 for carrying the storage container 102. Note that the load lock chamber 520 of the present embodiment is also referred to as a front-side load lock chamber.

The loading/unloading port 515 is provided in the front side of the housing 521, and the loading/unloading port 515 is provided with the gate valve 524.

A loading/unloading port 525 for loading/unloading the substrate S from/into the inside of the housing 521 into/from a housing 531 of the vacuum carrier 530 is provided in a rear side of the housing 521. The loading/unloading port 525 is provided with a gate valve 534. Note that the gate valve 534 is provided on the vacuum carrier 530 side.

### —Rear-side Atmospheric Carrier—

The atmospheric carrier 550 includes a housing 551. An inside of the housing 551 is a transfer space 552 for carrying the storage container 102. Note that the atmospheric carrier 550 of the present embodiment is also referred to as a rear-side atmospheric carrier.

A loading/unloading port 555 is provided in a rear side of the housing 551, and an opener 554 is provided near the loading/unloading port 555.

A loading/unloading port 545 for loading/unloading the substrate S taken out from the storage container 102 from/into the housing 551 into/from a housing 541 of the load lock chamber 540 is provided in a front side of the housing 551. The loading/unloading port 545 is provided with a gate valve 544. The gate valve 544 is provided on the load lock chamber 540 side.

The atmospheric carrier 550 includes an atmospheric carry robot 553 in the housing 551. The atmospheric carry robot 553 takes out the substrate S from the storage container 102 on a table 186, and places the substrate S on a substrate placing table 543 of the load lock chamber 540. The atmospheric carry robot 553 can also return the substrate S from the substrate placing table 543 to the storage container 102. That is, the atmospheric carry robot 553 can carry the substrate S between the second container mover 180 and the load lock chamber 540.

### —Rear-Side Load Lock Chamber—

The load lock chamber 540 includes the housing 541. An inside of the housing 541 is a transfer space 542 for carrying the storage container 102. Note that the load lock chamber 540 of the present embodiment is also referred to as a rear-side load lock chamber.

The loading/unloading port 545 is provided in the rear side of the housing 541, and the loading/unloading port 545 is provided with the gate valve 544.

A loading/unloading port 537 for loading/unloading the substrate S from/into the inside of the housing 541 into/from the housing 531 of the vacuum carrier 530 is provided in a front side of the housing 541. The loading/unloading port 537 is provided with a gate valve 536. Note that the gate valve 536 is provided on the vacuum carrier 530 side.

### —Vacuum Carrier—

In the vacuum carrier 530, a plurality of the reactors 300 is arranged on both sides in a width direction. Further, the vacuum carrier 530 is configured to be communicable with the plurality of reactors 300. Note that, in the present embodiment, as an example, five reactors 300 are provided on one side in the width direction of the vacuum carrier 530, and five reactors 300 are provided on the other side in the width direction of the vacuum carrier 530. When the reactors 300 are individually designated, the reactors 300 on one side in the width direction are referred to as a reactor 300a, a reactor 300b, a reactor 300c, a reactor 300d, and a reactor 300e in order from the front. Further, the reactors 300 on the other side in the width direction are referred to as a reactor 300f, a reactor 300g, a reactor 300h, a reactor 300i, and a reactor 300j in order from the front.

The vacuum carrier 530 of the present embodiment is also referred to as a lower vacuum carrier.

The vacuum carrier 530 includes the housing 531. An inside of the housing 531 is a transfer space 532 for carrying the storage container 102.

The loading/unloading port 525 is provided in the front side of the housing 531, and the loading/unloading port 525 is provided with the gate valve 534.

The loading/unloading port 537 for loading/unloading the substrate S from/into the inside of the housing 541 of the load lock chamber 540 into/from the housing 531 of the vacuum carrier 530 is provided in the rear side of the housing 521. The loading/unloading port 537 is provided with the gate valve 536.

Further, the housing 531 is provided with a rail 533 on which a vacuum carry robot 535 to be described below moves. Specifically, the rail 533 is provided at a lower portion of the housing 531 and extends in the front-rear direction. In other words, the rail 533 extends from the loading/unloading port 525 toward the loading/unloading port 537 or from the loading/unloading port 537 toward the loading/unloading port 525.

The vacuum carrier 530 is provided with the vacuum carry robot 535 as an example of a substrate carry robot capable of carrying the substrate S to each reactor 300. In other words, the vacuum carrier 530 includes the vacuum carry robot 535 in the housing 521. Further, in the present embodiment, the vacuum carrier 530 includes a plurality of the vacuum carry robots 535.

The vacuum carry robot 535 is movable along the rail 533 on the rail 533. The vacuum carry robot 535 is configured to be able to mount a plurality of the substrates S. That is, the vacuum carry robot 535 can move on the rail 533 in a state of mounting (holding) the plurality of substrates S to carry the substrates S to the target reactor 300.

Further, in the present embodiment, the vacuum carrier 530 includes the plurality of vacuum carry robots 535. A corresponding reactor 300 is set in each of the plurality of vacuum carry robots 535. Specifically, the vacuum carrier 530 includes two vacuum carry robots 535, and one vacuum carry robot 535 is provided in front of the other vacuum carry robot 535 on the rail 143. Hereinafter, the vacuum carry robot 535 disposed on the front side is referred to as a front-side vacuum carry robot 535a, and the vacuum carry robot 535 disposed on the rear side is referred to as a rear-side vacuum carry robot 535b. The front-side vacuum carry robot 535a of the present embodiment is an example of a first substrate carry robot in the present disclosure, and the rear-side vacuum carry robot 535b of the present embodiment is an example of a second substrate carry robot in the present disclosure.

The front-side vacuum carry robot 535a of the present embodiment is in charge of the reactors 300 arranged on the front side among the plurality of reactors 300. Specifically, the front-side vacuum carry robot 535a is in charge of the reactor 300a, the reactor 300b, the reactor 300f, and the reactor 300g. Note that, in the present embodiment, since five reactors 300 are arranged on each side, the front-side vacuum carry robot 535a is also in charge of the reactor 300c and the reactor 300h located in the center in the front-rear direction. In other words, the front-side vacuum carry robot 535a carries the substrate S to the reactor 300a, the reactor 300b, the reactor 300c, the reactor 300f, the reactor 300g, and the reactor 300h.

The rear-side vacuum carry robot 535b of the present embodiment is in charge of the reactors 300 arranged on the rear side among the plurality of reactors 300. Specifically, the rear-side vacuum carry robot 535b is in charge of the reactor 300d, the reactor 300e, the reactor 300i, and the reactor 300j. In other words, the rear-side vacuum carry robot 535b carries the substrate S to the reactor 300d, the reactor 300e, the reactor 300i, and the reactor 300j.

Further, in a case where the plurality of reactors 300 can perform different substrate processing, transfer areas (the reactors 300 in charge) of the front-side vacuum carry robot 535a and the rear-side vacuum carry robot 535b may be set according to types of the substrate processing by the reactors 300.

Furthermore, the transfer areas (the reactors 300 in charge) of the front-side vacuum carry robot 535a and the rear-side vacuum carry robot 535b may be set according to a time of the substrate processing by the reactor 300.

Furthermore, in the case where the plurality of reactors 300 can perform different substrate processing, the vacuum carry robot 535 may be set to move to a different reactor (another reactor) 300 after processing the substrate S in a certain reactor 200.

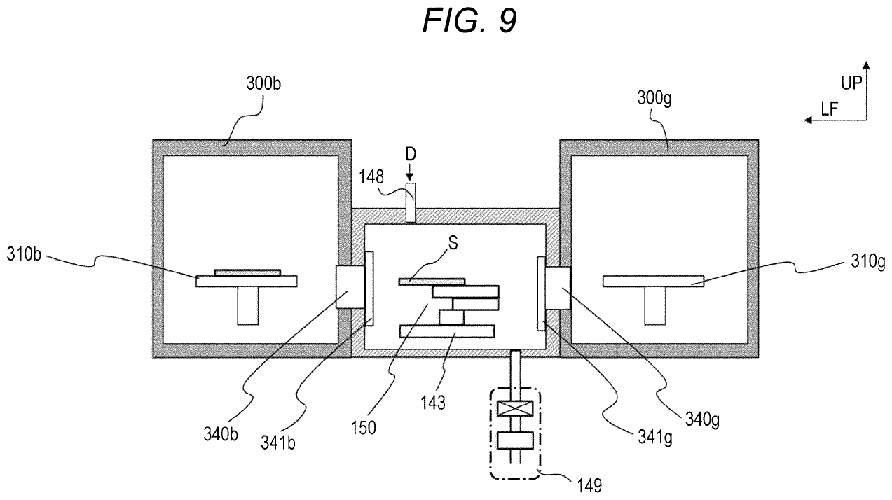

Further, as illustrated in FIG. 9, the vacuum carrier 530 includes an inert gas supplier 148 and an exhauster 149. The inert gas supplier 148 is configured to supply an inert gas into the housing 531. When the inert gas is supplied into the housing 531, the transfer space 532 becomes an inert gas atmosphere. The exhauster 149 is a portion that exhausts the atmosphere in the housing 531.

The operation of each part of the substrate carrier 140 is controlled by a controller 400. As an example, the controller 400 sets the transfer areas (the reactors 300 in charge) of the plurality of vacuum carry robots 535.

### (Reactor: Sheet)

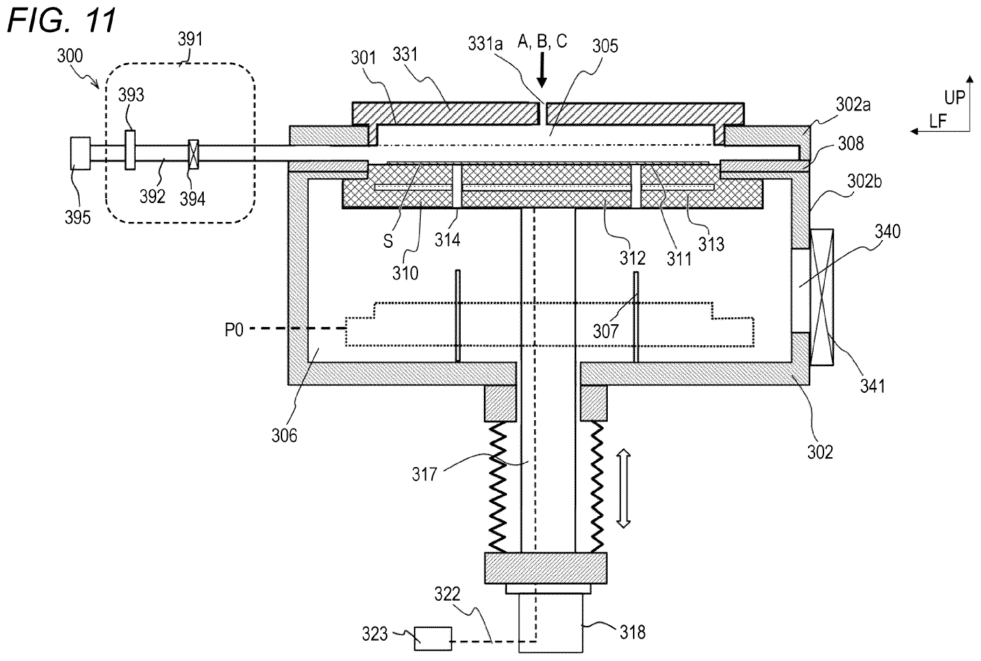

Next, the reactor 300 will be described with reference to FIG. 11. As illustrated in FIG. 11, the reactor 300 includes a container 302. In the container 302, a process chamber 301 constituting a processing space 305 for processing the substrate S and a transfer chamber 306 having a transfer space through which the substrate S passes when the substrate S is carried to the processing space 305 are formed. The container 302 includes an upper container 302a and a lower container 302b. A partition 308 is provided between the upper container 302a and the lower container 302b.

A loading/unloading port 340 adjacent to a gate valve 341 is provided in a side surface of the lower container 302b, and the substrate S moves between the lower container 302b and the vacuum carrier 530 via the loading/unloading port 340. At a bottom of the lower container 302b, a plurality of lift pins 307 is disposed.

In the processing space 305, a substrate support 310 that supports the substrate S is disposed. The substrate support 310 mainly includes a substrate placing surface 311 on which the substrate S is placed, a substrate placing table 312 having the substrate placing surface 311 on a surface thereof, and a heater 313 serving as a heater provided in the substrate placing table 312. In the substrate placing table 312, through-holes 314 through which lift pins 307 pass are formed at positions corresponding to the lift pins 307, respectively.

Wiring 322 for supplying power is connected to the heater 313. The wiring 322 is connected to a heater controller 323. The heater controller 323 is electrically connected to the controller 400. The controller 400 controls the heater controller 323 to operate the heater 313.

The substrate placing table 312 is supported by a shaft 317. The shaft 317 penetrates a bottom of the container 302 and is further connected to a lift 318 outside the container 302.

By operating the lift 318 to raise and lower the shaft 317 and the substrate placing table 312, the substrate placing table 312 can raise and lower the substrate S placed on the substrate placing surface 311.

The process chamber 301 includes the substrate placing table 312. Note that the process chamber 301 only needs to be able to secure the processing space 305 for processing the substrate S, and may be configured by another structure.

When the substrate S is carried, the substrate placing table 312 lowers the substrate placing surface 311 to a carry position P0 facing the loading/unloading port 340, and when the substrate S is processed, as illustrated in FIG. 11, the substrate S rises to a processing position in the processing space 305.

A lid 331 of the process chamber 301 is provided with a gas introduction hole 331a. A first gas supplier 224, a second gas supplier 225, and an inert gas supplier 226 are connected to the gas introduction hole 331a. As a result, a first gas, a second gas, and an inert gas are supplied to the process chamber 301.

Next, an exhauster 391 will be described. An exhaust pipe 392 communicates with the processing space 305. The exhaust pipe 392 is connected to the upper container 302a so as to communicate with the processing space 305. The exhaust pipe 392 is provided with an APC 393 that is a pressure controller for controlling the inside of the processing space 305 to a predetermined pressure. The APC 393 has a valve body (not illustrated) whose opening degree is regulatable, and regulates conductance of the exhaust pipe 392 according to an instruction from the controller 400. A valve 394 is provided on a downstream side of the APC 393 in the exhaust pipe 392. A dry pump 395 is provided upstream of the exhaust pipe 392. The dry pump 395 exhausts the atmosphere of the processing space 305 via the exhaust pipe 392.

Next, a substrate processing step using the substrate processing apparatus 600 of the present embodiment will be described. Note that description of similar steps to those of the substrate processing apparatus 100 of the first embodiment will be omitted.

### [Container Moving Step]

A container moving step will be described.

First, the substrate processing apparatus 600 receives the storage container 102 supported by the support table 111 of the load port 110 by the robot 124 of the first container mover 120. As a result, the storage container 102 moves from the load port 110 to the first container mover 120.

Next, the substrate processing apparatus 600 carries the substrate S stored in the storage container 102 from the first container mover 120 to the transfer target reactor 300 via the substrate carrier 500. Specifically, the storage container 102 (substrate S) is sent toward the vacuum carry robot 535 in charge of the transfer target reactor 300, and the substrate S is carried from the vacuum carry robot 535 to the reactor 300.

For example, in a case where the front-side vacuum carry robot 535a is in charge of the transfer target reactor 300, the storage container 102 is placed on the table 127 using the robot 124 and the elevator 123. Next, the lid of the storage container 102 is opened by the opener 145. Then, the atmospheric carry robot 513 takes out the substrate S from the storage container 102 and places the substrate S on the substrate placing table 523. The front-side vacuum carry robot 535a receives the substrate S placed on the substrate placing table 523, and carries the substrate S to the transfer target reactor 300. Thereafter, the gate valve 341 of the transfer target reactor 300 is opened, and the front-side vacuum carry robot 535a transfers the substrate S to the substrate placing table 312 of the transfer target reactor 300. That is, in the case where the front-side vacuum carry robot 535a is in charge of the transfer target reactor 300, the substrate S is loaded into the transfer target reactor 300 via the first container mover 120 and the substrate carrier 500.

Meanwhile, in a case where the rear-side vacuum carry robot 535b is in charge of the transfer target reactor 300, the storage container 102 is placed on the table 125 using the robot 124 and the elevator 123. Next, the storage container 102 supported by the table 125 is placed on the table 185 of the second container mover 180 by the container carrier 162 of the third container mover 160. Next, the storage container 102 is moved from the table 185 to the table 186 using the robot 184 and the elevator 183. Next, the lid of the storage container 102 is opened by the opener 554. Then, the rear-side vacuum carry robot 535b takes out the substrate S from the storage container 102 and places the substrate S on the substrate placing table 543. The rear-side vacuum carry robot 535b receives the substrate S placed on the substrate placing table 543, and carries the substrate S to the transfer target reactor 300. Thereafter, the gate valve 341 of the transfer target reactor 300 is opened, and the rear-side vacuum carry robot 535b transfers the substrate S to the substrate placing table 312 of the transfer target reactor 300. That is, in the case where the rear-side vacuum carry robot 535b is in charge of the transfer target reactor 300, the substrate S is loaded into the transfer target reactor 300 via the first container mover 120, the third container mover 160, the second container mover 180, and the substrate carrier 500. Note that, in the present embodiment, when the substrate S is loaded into the substrate carrier 500, the inert gas supplier 148 and the exhauster 149 are regulated so that each atmosphere of the load lock chamber 520, the vacuum carrier 530, and the load lock chamber 540 becomes an inert gas atmosphere.

### [Substrate Loading Step]

Next, the substrate loading step will be described. In the substrate loading step, the substrate placing table 312 supporting the substrate S is raised and loaded into the process chamber 301 as illustrated in FIG. 11. Note that the heater 313 is in an operating state and is maintained at a processing temperature of the substrate S.

Subsequently, the inside of the process chamber 301 is set to a predetermined pressure by cooperation of the inert gas supplier 226 and the exhauster 391.

### [Film Processing Step]

Next, a film processing step will be described. The film processing step is a step of processing a film formed on the substrate S in the reactor 300. When the process chamber 301 has a desired pressure, the first gas supplier 224 and the second gas supplier 225 are controlled to supply the first gas and the second gas into the process chamber 301 to process the substrate S. The processing in this step refers to, for example, processing of causing the first gas to react with the second gas to form a predetermined film on the substrate S. In the present embodiment, for example, HCDS is supplied as the first gas and NH₃ gas is supplied as the second gas to form a silicon nitride (SiN) film.

Note that conditions of this step are similar to those of the first embodiment. Therefore, detailed description is omitted.

When a predetermined time has elapsed, the first gas supplier 224 and the second gas supplier 225 are stopped. Further, the inert gas is supplied from the inert gas supplier 226 to exhaust the atmosphere in the process chamber 301.

### [Substrate Unloading Step]

A substrate unloading step will be described. After a lapse of a predetermined time, the substrate placing table 312 is lowered. When the substrate placing table 312 is lowered, the substrate S is unloaded by a method reverse to the method of loading the substrate S.

Since the substrate processing apparatus 600 according to the present embodiment can obtain similar function effects to the substrate processing apparatus 100 of the first embodiment, detailed description of the function effects is omitted.

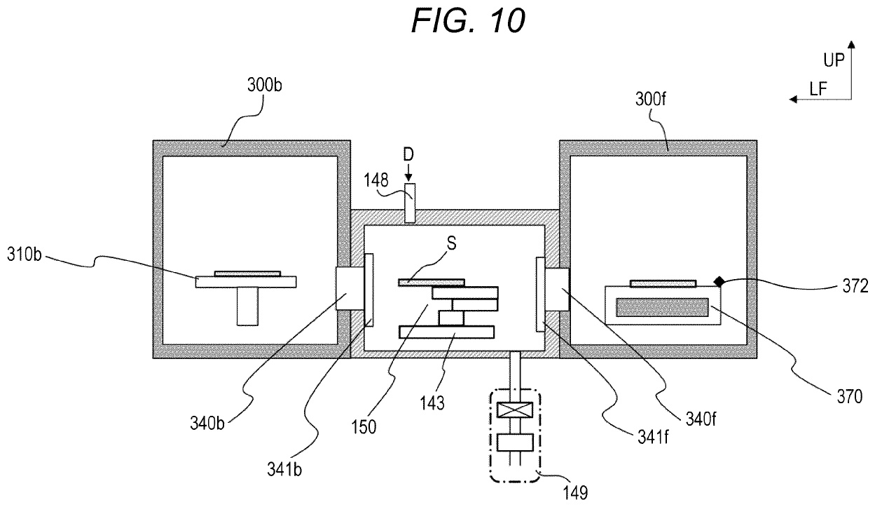

In the substrate processing apparatus 600 according to the present embodiment, all the reactors 300 are used for film formation, but the present disclosure is not limited thereto. For example, as illustrated in FIG. 10, one of the reactors 300 may be dedicated to cooling. That is, the substrate processing apparatus 600 may include a cooling module 370 in at least one of the reactors 300. The cooling module 370 may be provided with a temperature sensor 372 that monitors the temperature of the substrate S. By providing the cooling module 370 in at least one of the reactors 300 and cooling the processed substrates S by the cooling module 370, it is possible to alleviate congestion of the processing of the substrates S and enhance processing efficiency of the entire apparatus.

### Third Embodiment

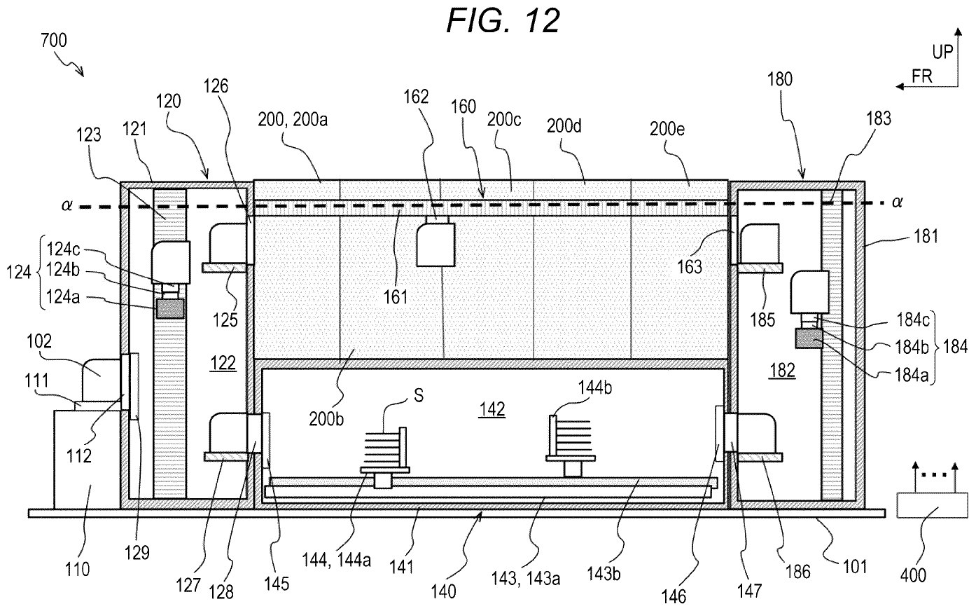

Next, a substrate processing apparatus 700 according to a third embodiment of the present disclosure will be described with reference to FIG. 12.

The substrate processing apparatus 700 of the present embodiment is different from the substrate processing apparatus 100 of the first embodiment in that a rail 143 is provided laterally (in a width direction) for each of a plurality of carry robots 144, and the other parts have the same configurations. Therefore, description of similar configurations to those of the substrate processing apparatus 100 of the first embodiment will be omitted.

A substrate carrier 140 of the substrate processing apparatus 700 includes a plurality of the rails 143. Specifically, the substrate carrier 140 includes a rail 143a for a carry robot 144a and a rail 143b for a carry robot 144b.

A controller 400 of the substrate processing apparatus 700 is configured to perform setting such that when a failure has occurred in any one of the carry robots 144, the other carry robot 144 is also in charge of the reactor 200 that the carry robot 144 in which the failure has occurred is in charge of.

Next, function effects of this embodiment will be described.

In the substrate processing apparatus 700, since a dedicated path, that is, the dedicated rail 143 is provided for each of the plurality of carry robots 144, it is possible to prevent congestion of the carry robots 144.

Furthermore, in the substrate processing apparatus 700, even in the case where a defect has occurred in any of the carry robots 144, the carry processing of the substrate S can be continued by another carry robot 144 with no defect.

The configuration in which the dedicated path, that is, the dedicated rail 143 is provided laterally (in the width direction) for each of the plurality of carry robots 144 of the third embodiment may also be applied to the second embodiment described above.

### Fourth Embodiment

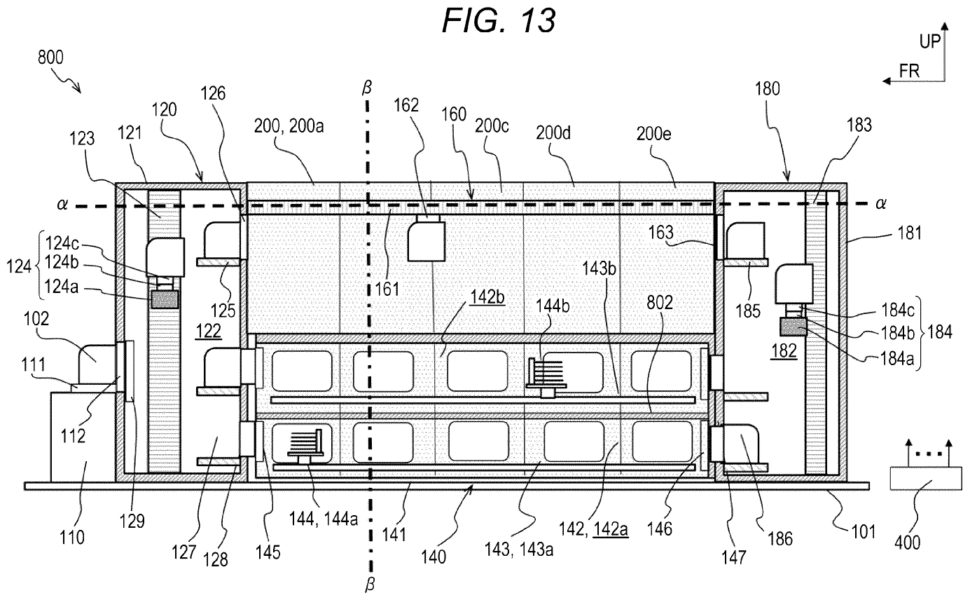

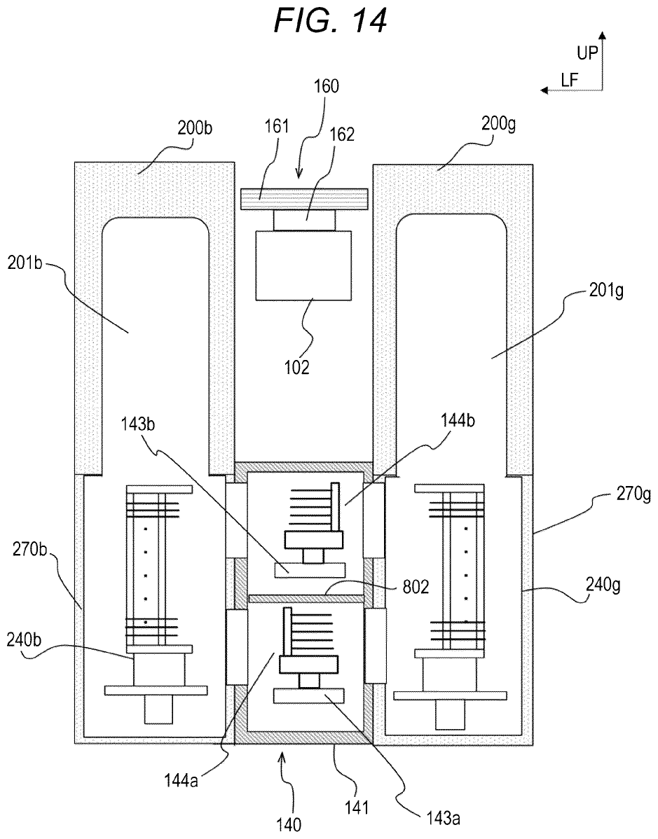

Next, a substrate processing apparatus 800 according to a fourth embodiment of the present disclosure will be described with reference to FIGS. 13 and 14.

The substrate processing apparatus 800 of the present embodiment is different from the substrate processing apparatus 100 of the first embodiment in that rails 143 are provided up and down for each of a plurality of carry robots 144, and the other parts have the same configurations. Therefore, description of similar configurations to those of the substrate processing apparatus 100 of the first embodiment will be omitted.

In a substrate carrier 140 of the substrate processing apparatus 800, an inside of a housing 141 is partitioned up and down by a partition 802. That is, a transfer space 142 is divided into a lower transfer space 142a on a lower side and an upper transfer space 142b on an upper side by the partition 802.

The substrate carrier 140 of the substrate processing apparatus 800 includes a plurality of the rails 143. Specifically, the substrate carrier 140 includes a rail 143a for a carry robot 144a and a rail 143b for a carry robot 144b. Further, the rail 143a and the rail 143b are arranged to be separated from each other in an up-down direction. In the present embodiment, the rail 143a is arranged in a lower transfer space 142a, and the rail 143b is arranged in an upper transfer space 142b. That is, the rail 143b is arranged above the rail 143a. Note that the rail 143a and the rail 143b are provided so as not to overlap each other in the up-down direction (vertical direction).

As illustrated in FIG. 13, a loading/unloading port of the reactor 200 is set to a height of each rail 143. Specifically, the loading/unloading port of the reactor 200 is provided at a height at which the carry robot 144a moving on the rail 143a can transfer a substrate S to the reactor 200. Further, the loading/unloading port of the reactor 200 is provided at a height at which the carry robot 144b moving on the rail 143b can transfer the substrate S to the reactor 200. In the present embodiment, the lower transfer space 142a and the upper transfer space 142b are provided with the same number of loading/unloading ports as the number of the reactors 200.

Next, function effects of this embodiment will be described.

In the substrate processing apparatus 800, since a dedicated path, that is, the dedicated rail 143 is provided for each of the plurality of carry robots 144, it is possible to prevent congestion of the carry robots 144.

Furthermore, in the substrate processing apparatus 800, even in the case where a defect has occurred in any of the carry robots 144, the carry processing of the substrate S can be continued by another carry robot 144 with no defect.

Then, in the substrate processing apparatus 700, the footprint can be reduced by providing the rails 143 in the up-down direction.

In the above-described fourth embodiment, the inside of the housing 141 is partitioned up and down by the partition 802, but the present disclosure is not limited to this configuration. For example, the inside of the housing 141 may not be partitioned by the partition 802, and the rail 143b may be arranged above the rail 143a. Also in this case, function effects similar to those of the fourth embodiment can be obtained.

The configuration in which the rail 143 is provided in the up-down direction (vertical direction) for each of the plurality of carry robots 144 according to the fourth embodiment described above may also be applied to the second embodiment described above.

### Fifth Embodiment

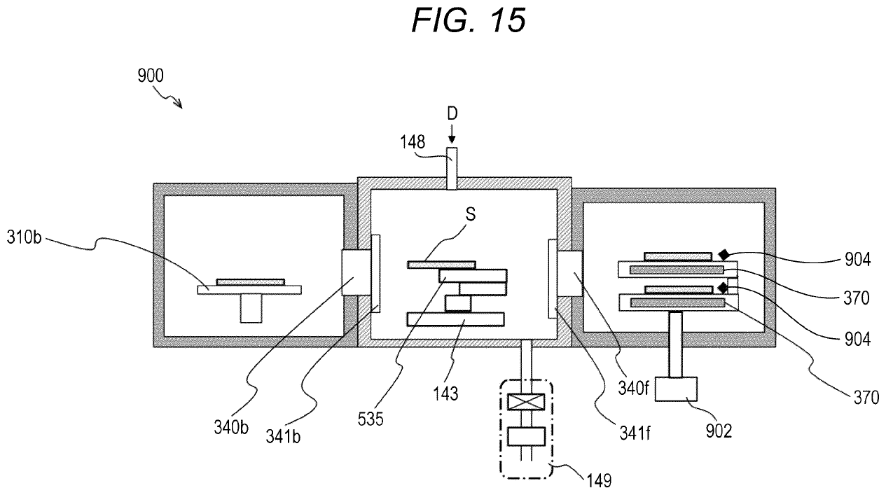

Next, a substrate processing apparatus 900 according to a fifth embodiment of the present disclosure will be described with reference to FIG. 15.

The substrate processing apparatus 900 of the present embodiment has a similar configuration to the substrate processing apparatus 600 of the second embodiment except that at least one of reactors 300 is dedicated to cooling. Therefore, in the present embodiment, the reactor 300 dedicated to cooling will be described. Description of similar configurations to those of the substrate processing apparatus 100 of the second embodiment will be omitted.

In the substrate processing apparatus 900 according to the present embodiment, as illustrated in FIG. 15, one of reactors 300 is dedicated to cooling. That is, the substrate processing apparatus 900 includes a cooling module 370 in at least one of the reactors 300. By providing the cooling module 370 in at least one of the reactors 300 in this manner, a processed substrate S can be cooled by the cooling module 370. As an example, the cooling module 370 of the present embodiment includes an inner cooling mechanism and an outer shell constituting an outer side and on which the substrate S is placed.

The reactor 300 dedicated to cooling is provided with a lifting unit 902 as an example of an elevator. The lifting unit 902 moves the cooling modules 370 in a plurality of stages in an up-down direction. The cooling modules 370 of the respective stages are arranged to be separated in the up-down direction.

Further, a temperature sensor 904 is attached to each cooling module 370, and the temperature sensor 904 monitors a temperature state of the substrate S.

In the present embodiment, since the cooling modules 370 in the plurality of stages is provided, it is possible to alleviate congestion of processing of the substrates S and enhance processing efficiency of the entire apparatus by efficiently cooling the processed substrates S with the cooling modules 370.

Further, in the present embodiment, since the processed substrate S is cooled in a place where no vacuum carry robot 535 is stored, reduction in transfer efficiency of the vacuum carry robot 535 can be prevented.

In the present embodiment, at least one reactor 300 is dedicated to cooling, but the present disclosure is not limited to this configuration. For example, a cooling mechanism or the like may be provided on a substrate placing table 543 of a housing 541 to cool the placed substrate S. In addition, a chamber dedicated to cooling may be provided separately from the reactor 300. Furthermore, a cooling mechanism may be provided on a table 127 and a table 186 to cool the substrate S.

### OTHER EMBODIMENTS

Further, in the above-described embodiment, an example in which five reactors 200 are used on each side in the width direction, that is, a total of ten reactors are used as the substrate processing apparatus 100, has been described. However, the embodiment is not limited thereto, and a substrate processing apparatus using six reactors 200 on each side in the width direction, that is, a total of twelve reactors 200 or more may be used, or a substrate processing apparatus using four reactors 200 on each side in the width direction, that is, a total of eight reactors 200 or less reactors may be used.

Further, in each of the above-described embodiments, in the film forming processing performed by the substrate processing apparatus, the case in which the HCDS gas is used as the first element-containing gas (first gas) and the NH₃ gas is used as the second element-containing gas (second gas), and the SiN film is formed on the substrate S, has been exemplified, but the present disclosure is not limited thereto. That is, the processing gas used for the film forming processing is not limited to the HCDS gas, the NH₃ gas, or the like, and another type of thin film may be formed using another type of gas. Furthermore, three or more types of processing gases may be used. Further, the first element may be any of various elements, for example, titanium (Ti), zirconium (Zr), or hafnium (Hf), instead of Si. Further, the second element may be, for example, nitrogen (N), instead of H.

In addition, for example, in each of the above-described embodiments, the film forming processing has been described as an example of the processing performed by the substrate processing apparatus, but the present disclosure is not limited thereto. That is, the present disclosure can also be applied to film forming processing and the modification processing other than the thin film forming processing exemplified in each of the embodiments in addition to the film forming processing exemplified in each of the embodiments. Further, the specific content of the substrate processing may be any content, and the present disclosure can be applied not only to the film forming processing and the modification processing but also to other substrate processing such as annealing processing, diffusing processing, oxidizing processing, nitriding processing, and lithography processing. Furthermore, the present disclosure can also be applied to, for example, another substrate processing apparatus such as an annealing processing apparatus, an etching apparatus, an oxidizing processing apparatus, nitriding a processing apparatus, an exposure apparatus, a coating apparatus, a drying apparatus, a heating apparatus, or a processing apparatus using plasma. Part of the constituents in an embodiment can be replaced with a constituent in another embodiment. A constituent in an embodiment can be added to the constituents in another embodiment. Part of the constituents in each embodiment can be given another constituent, can be deleted, or can be replaced with another constituent.

According to the present disclosure, it is possible to achieve cost reduction and throughput improvement by carrying a container in which a substrate is accommodated.

What is claimed is:

1. A substrate processing apparatus comprising:
a first container mover capable of moving a container;
a second container mover disposed at a position different from the first container mover and capable of moving the container;
a plurality of process modules capable of processing a substrate accommodated in the container;
a substrate carrier disposed between the first container mover and the second container mover, configured to be communicable with the plurality of process modules, and capable of carrying the substrate;
a substrate carry robot provided in the substrate carrier and capable of carrying the substrate to the process module;
a third container mover disposed between the first container mover and the second container mover, and capable of moving the container from the first container mover to the second container mover; and
a controller.

2. The substrate processing apparatus according to claim 1, wherein
the first container mover includes
a first container carrier,
a first container table adjacent to the third container mover, and
a second container table adjacent to the substrate carrier.

3. The substrate processing apparatus according to claim 2, wherein
a load port is adjacent to the first container mover, and
the controller is configured to be capable of controlling the first container carrier so as to move the container supported by the load port to the first container table or the second container table.

4. The substrate processing apparatus according to claim 1, wherein
the second container mover includes
a second container carrier,
a third container table adjacent to the second container mover, and
a fourth container table adjacent to the substrate carrier.

5. The substrate processing apparatus according to claim 4, wherein the controller is configured to be capable of controlling the second container carrier so as to move the container in the first container mover to the third container table via the third container mover and then cause the fourth container table to support the container.

6. The substrate processing apparatus according to claim 1, wherein the third container mover is capable of carrying the container in an atmosphere independent of the substrate carrier.

7. The substrate processing apparatus according to claim 1, wherein
the first container mover includes
a first container carrier,
a first container table adjacent to the second container mover, and
a second container table adjacent to the substrate carrier,
and
the second container mover includes
a second container carrier,
a third container table adjacent to the second container mover, and
a fourth container table adjacent to the substrate carrier,
and
in the second container table, the container is disposed such that a lid of the container faces the substrate carrier, and in the fourth container table, the container is disposed such that the lid of the container faces the substrate carrier.

8. The substrate processing apparatus according to claim 1, further comprising: a rotator configured to rotate the container in a horizontal direction.

9. The substrate processing apparatus according to claim 8, wherein the rotator is provided in the third container mover.

10. The substrate processing apparatus according to claim 1, wherein the substrate carrier includes a plurality of the substrate carry robots, and process modules respectively in charge of the plurality of substrate carry robots are set.

11. The substrate processing apparatus according to claim 1, wherein
the substrate carrier includes a first substrate carry robot disposed on a front side and a second substrate carry robot disposed on a back side, and
the first substrate carry robot is in charge of the process module disposed on the front side, and
the second substrate carry robot is in charge of the process module disposed on the back side.

12. The substrate processing apparatus according to claim 11, wherein
each of the plurality of process modules is capable of different processing, and
a transfer area is set according to a type of the processing for
the first substrate carry robot and the second substrate carry robot.

13. The substrate processing apparatus according to claim 12, wherein
a transfer area is set according to a time of the processing for
the first substrate carry robot and the second substrate carry robot.

14. The substrate processing apparatus according to claim 12, wherein the controller is configured to be capable of, when a failure has occurred in any of the substrate carry robots, performing to set so that another of the substrate carry robots is also in charge of the process module that the substrate carry robot in which the failure has occurred is in charge of.

15. The substrate processing apparatus according to claim 1, wherein
the substrate carrier includes
a rail on which the substrate carry robot is movable, and
a plurality of the substrate carry robots supported by the rail.

16. The substrate processing apparatus according to claim 1, wherein
the substrate carrier includes
the plurality of substrate carry robots, and
a plurality of rails corresponding to the respective substrate carry robots and capable of supporting the respective substrate carry robots.

17. The substrate processing apparatus according to claim 16, wherein
the rails are provided so as not to overlap each other in a vertical direction, and
a substrate loading/unloading port of the process module is set to a height of each of the rails.

18. The substrate processing apparatus according to claim 1, further comprising
a substrate cooling module in a space different from a space in which the substrate carry robot is stored, wherein
the substrate cooling module includes an elevator, and is capable of cooling and lifting the plurality of substrates.

19. A method of processing a substrate including:
loading a substrate into a process module among a plurality of process modules via a first container mover capable of moving a container accommodating the substrate and the substrate carrier disposed between the first container mover and a second container mover disposed at a position different from the first container mover and capable of moving the container, configured to be communicable with the plurality of process modules, and capable of carrying the substrate;
and processing the substrate in the process module;
or loading the substrate into the process module via the first container mover, a third container mover disposed between the first container mover and the second container mover, the second container mover, and the substrate carrier,
and processing the substrate in the process module.

20. A method of manufacturing a semiconductor device, comprising the method of claim 19.

21. A non-transitory computer-readable recording medium storing a program that causes, by a computer, a substrate processing apparatus to perform a process comprising:
loading a substrate into the process module among a plurality of process modules via a first container mover capable of moving a container accommodating the substrate and the substrate carrier disposed between the first container mover and a second container mover disposed at a position different from the first container mover and capable of moving the container, configured to be communicable with the plurality of process modules, and capable of carrying the substrate;
and processing the substrate in the process module;
or loading the substrate into the process module via the first container mover, a third container mover disposed between the first container mover and the second container mover, the second container mover, and the substrate carrier,
and processing the substrate in the process module.
